(19) United States
(12) Patent Application Publication
(10) Pub. No.: US 2023/0216494 A1
(43) Pub. Date: Jul. 6, 2023

(54) DC SERIES RF PARALLEL PIN DIODE SWITCH

(71) Applicant: Gideon van Zyl, Fort Collins, CO (US)

(72) Inventor: Gideon van Zyl, Fort Collins, CO (US)

(21) Appl. No.: 18/093,746

(22) Filed: Jan. 5, 2023

Related U.S. Application Data
(60) Provisional application No. 63/297,071, filed on Jan. 6, 2022.

(51) Int. Cl. H03K 17/74

(52) U.S. Cl. CPC H03K 17/74; H03K 2217/0081; H03K 2217/0036

(57) ABSTRACT

This disclosure describes systems, methods, and apparatuses for a PIN diode switch comprising series connected PIN diodes, the series connected PIN diodes comprising two or more PIN diodes connected in series, wherein each of the two or more PIN diodes comprises a first node and a second node; and an internal node positioned where a first node of a first PIN diode connects to a second node of a second, adjacent PIN diode; a RF bypass capacitor connected between a reference node and a first end of the series connected PIN diodes, and wherein a second end of the series connected PIN diodes is connected to the reference node; an RF circuit connected between the reference node and the internal node; and a PIN diode driver connected across the RF bypass capacitor.

### CLAIM OF PRIORITY UNDER 35 U.S.C. § 119

The present Application for Patent claims priority to Provisional Application No. 63/297,071 entitled “DC SERIES RF PARALLEL PIN DIODE SWITCH” filed Jan. 6, 2022, and assigned to the assignee hereof and hereby expressly incorporated by reference herein.

### FIELD OF THE DISCLOSURE

The present disclosure relates generally to diode switch circuits. Specifically, but without limitation, the present disclosure relates to a PIN diode switch circuit utilizing a DC-series RF-parallel arrangement of two or more PIN diodes.

### DESCRIPTION OF RELATED ART

PIN diodes are electrical devices having an un-doped or lightly doped intrinsic (I) semiconductor region sandwiched between heavily doped regions, and have various applications, for instance, as switching devices in impedance matching networks, especially in radio frequency (RF) matching networks.

The “PIN” designation derives from the three-part “sandwich” structure of this diode: a lightly doped intrinsic region (I) positioned between a heavily doped p-type semiconductor (P) and a heavily doped n-type semiconductor (N). In general, PIN diodes obey conventional diode behavior at low frequency input signals, but for higher frequency input signals they operate as a resistor in the forward biased or ON-state, and as a capacitor in the reverse biased or OFF-state. As such, PIN diodes are often utilized in radio frequency (RF) applications, e.g., in attenuators and fast switches where high isolation and low loss are desired. In some circumstances, PIN diodes can be turned ON with a DC current that is a small fraction of the RF current being switched and turned OFF by reverse biasing the PIN diode. PIN diodes are attractive switches because they combine low ON-state resistance with very low OFF-state losses. In some cases, a PIN diode driver circuit may be used to turn the PIN diode ON and OFF by conducting a DC current through the PIN diode and applying a reverse bias voltage across the PIN diode, respectively. In the OFF state, the PIN diode may be subjected to high RF voltages. In conventional PIN diode switch circuits, an RF blocking device (or RF choke) is placed between the PIN diode and the PIN diode driver circuit. Ideally, this RF blocking device must be designed to conduct DC current and withstand the high RF voltage applied across the PIN diode.

In one implementation, PIN diodes are used in an impedance match network configured to match a varying load impedance of a plasma load to a desired impedance (e.g., 50 ohm) into which a high-power RF generator can deliver power. In such an implementation, the PIN diodes serve to connect or disconnect reactive components, typically capacitors, of the impedance matching network to quickly alter the properties of the matching network by switching the reactive elements in and out of the network.

A major difficulty is designing an effective RF blocking device between the PIN diode driver and the PIN diode. This RF blocking device should carry high DC currents to quickly charge and discharge the PIN diode and provide low RF losses when subjected to high levels of RF voltage. In the case of a new class of high-speed drivers with energy recovery, this RF blocking device is a major impediment to PIN diode switch circuit performance. Thus, there is a need for a refined PIN diode switch circuit that does not require a RF blocking device that is subjected to high levels of RF voltage.

The description provided in the description of related art section should not be assumed to be prior art merely because it is mentioned in or associated with this section. The description of related art section may include information that describes one or more aspects of the subject technology.

### SUMMARY OF THE DISCLOSURE

The following presents a simplified summary relating to one or more aspects and/or embodiments disclosed herein. As such, the following summary should not be considered an extensive overview relating to all contemplated aspects and/or embodiments, nor should the following summary be regarded to identify key or critical elements relating to all contemplated aspects and/or embodiments or to delineate the scope associated with any particular aspect and/or embodiment. Accordingly, the following summary has the sole purpose to present certain concepts relating to one or more aspects and/or embodiments relating to the mechanisms disclosed herein in a simplified form to precede the detailed description presented below.

Aspects of the present disclosure generally relate to systems, methods, and apparatuses for radio frequency (RF) switching circuits, and more particularly for a PIN diode switch circuit for high speed, high repetition rate and/or high-power applications. In one example, the PIN diode switch circuit includes two or more PIN diodes connected in series between a first node and a reference node, and a RF bypass capacitor connected between the first node and the reference node. In some cases, a PIN diode driver is connected across the RF bypass capacitor. In some examples, the remainder of the RF circuitry is connected between an internal node of the series connected PIN diodes (i.e., internal to the string of series connected PIN diodes, for instance, a node between a first PIN diode and a second, adjacent PIN diode) and the reference node.

In another example, a PIN diode switch circuit includes two or more PIN diodes connected in series between a first node and a second node, a first RF bypass capacitor connected between the first node and the reference node, and a second RF bypass capacitor connected between the second node and the reference node. Additionally, a first PIN diode driver is connected across the first RF bypass capacitor, and a second PIN diode driver is connected across the second RF bypass capacitor. In some examples, the remainder of the RF circuitry (e.g., RF circuitry 318, 328, 338 in FIGS. 3A, 3B, and 3C, respectively) is connected between an internal node of the series connected PIN diodes (i.e., internal to the string of series connected PIN diodes, for instance, a node between a first PIN diode and a second, adjacent PIN diode) and the reference node. In some embodiments, for instance, for PIN diode driver circuits incorporating a plurality of PIN diode drivers, a DC-passing RF-blocking circuit may be connected between the internal node (e.g., internal node 365 in FIG. 3F) and the reference node (e.g., reference node 367) to compensate for differences (if any) between the PIN diodes and/or PIN diode drivers. The PIN diode drivers may be selected from a class of two-stage PIN diode drivers with energy recovery, which facilitates in recovery of energy stored in the PIN diodes and/or RF bypass capacitors. In some instances, the PIN diode drivers my further incorporate one or more lower voltage reverse bias power supplies and associated switches to further limit losses, e.g., associated with charge removal from the intrinsic region of the PIN diode when switching from the ON to the OFF state.

In some cases, aspects of the present disclosure eliminate the need for an RF blocking device between the PIN diode driver and the PIN diode, and in other cases help reduce the requirements placed on the RF blocking device between the PIN diode driver and the PIN diode. Since the RF blocking device is an impediment to high-speed drivers, is typically bulky, and is a major source of RF losses and thus efficiency, the need for these RF blocking devices makes PIN-diode-switch-based matching networks unattractive in many applications. By eliminating or drastically reducing the design requirements placed on the RF blocking device (e.g., reducing voltage over the RF blocking device by a factor of 30 or more and/or RF losses by a factor 900 or more), tune range and efficiency may be enhanced for PIN-diode-switch-based matching networks, as compared to prior art techniques.

Some other embodiments of the disclosure can be characterized as a variable impedance matching network comprising a variable reactance element, the variable reactance element comprising at least a PIN diode coupled to a capacitor.

In some aspects, the techniques described herein relate to an apparatus including: series connected PIN diodes, the series connected PIN diodes comprising two or more PIN diodes connected in series between a first end and a second end, and an internal node positioned between two of the two or more PIN diodes; a first radio frequency (RF) bypass capacitor connected between a reference node and the first end of the series connected PIN diodes, and wherein a second end of the series connected PIN diodes is connected to the reference node; an RF circuit connected between the reference node and the internal node; and a first PIN diode driver connected across the first RF bypass capacitor.

In some aspects, the techniques described herein relate to an apparatus, wherein the series connected PIN diodes include an equal number of PIN diodes on either side of the internal node.

In some aspects, the techniques described herein relate to an apparatus, wherein the first PIN diode driver is configured to one or more of: supply a current through the series connected PIN diodes to turn the two or more PIN diodes ON; and supply a reverse bias voltage across the series connected PIN diodes to turn the two or more PIN diodes OFF. In some implementations of the apparatus, a magnitude of an impedance presented to the RF circuit is higher when the two or more PIN diodes are OFF as compared to when the two or more PIN diodes are ON.

In some aspects, the techniques described herein relate to an apparatus, where the apparatus is connected to an RF impedance matching network including one or more reactance elements. In some implementations, the apparatus is further configured to connect or disconnect at least one reactance element of the one or more reactance elements from a remainder of the RF impedance matching network.

In some aspects, the techniques described herein relate to an apparatus, where the first PIN diode driver includes a two-stage driver, the two-stage driver including a first resonant stage having a power supply; one or more switches and reactive elements for charging and discharging one or more of the first RF bypass capacitor, the series connected PIN diodes, and one or more capacitive elements in the RF circuit from and to the power supply; and a second holding stage. In some implementations, the second holding stage is configured to one or more of: hold a reverse bias voltage over the series connected PIN diodes, and supply current through the series connected PIN diodes. In some examples, the series connected PIN diodes are in an OFF state when the reverse bias voltage is applied. Additionally, the series connected PIN diodes are in an ON state when current is supplied through the series connected PIN diodes.

In some aspects, the techniques described herein relate to an apparatus, where a second end of the series connected PIN diodes is connected to the reference node via a second RF bypass capacitor, the apparatus further including a second PIN diode driver connected across the second RF bypass capacitor.

In some aspects, the techniques described herein relate to an apparatus, where the second PIN diode driver is a complementary PIN diode driver producing voltage and current of an opposite polarity than that of the first PIN diode driver.

In some aspects, the techniques described herein relate to an apparatus, further including a device (e.g., a DC passing RF blocking device) connected between the internal node and the reference node, where the DC passing RF blocking device presents low resistance to DC current and an impedance of large magnitude to RF current. In some examples, the device (i.e., the DC passing RF blocking device) is selected from a group consisting of an inductor, a parallel combination of an inductor and a capacitor, and a quarter RF wavelength long transmission line. Other types of DC passing RF blocking devices are contemplated in different embodiments and the examples listed herein are not intended to be limiting.

In some aspects, the techniques described herein relate to an apparatus, where the first RF bypass capacitor includes a plurality of capacitors connected in series, the apparatus further including: a plurality of DC passing RF blocking devices connected between internal nodes of the plurality of capacitors connected in series and internal nodes of the series connected PIN diodes. In some implementations, one or more of the plurality of DC passing RF blocking devices present low resistance to DC current and an impedance of large magnitude to RF current. Some non-limiting examples of such devices (i.e., DC passing RF blocking devices) include an inductor, a parallel combination of an inductor and a capacitor, and a quarter RF wavelength long transmission line (i.e., Δ/4 transmission line).

In some aspects, the techniques described herein relate to a method for driving series connected PIN diodes (also referred to as a series of PIN diodes) in a PIN diode switch, the series connected PIN diodes including two or more PIN diodes connected in series between a first end and a second end, the method including: supplying a current through the series connected PIN diodes to forward bias and turn the series connected PIN diodes ON, wherein RF circuitry is coupled between a reference node and an internal node, and a first RF bypass capacitor is connected between the first end of the series connected PIN diodes and the reference node, the internal node positioned between two of the two or more PIN diodes; and supplying a reverse bias voltage across the series connected PIN diodes to turn the series connected PIN diodes OFF. In some implementations of the method, a first impedance is presented to the RF circuitry when the series connected PIN diodes are ON, and a second impedance is presented to the RF circuitry when the series connected PIN diodes are OFF. In some implementations of the method, a magnitude of the second impedance is greater than a magnitude of the first impedance.

In some aspects, the techniques described herein relate to a method, where the second end of the series connected PIN diodes is coupled to the reference node.

In some aspects, the techniques described herein relate to a method, where the second end of the series connected PIN diodes is coupled to the reference node via a second RF bypass capacitor.

In some aspects, the techniques described herein relate to a method, where a first PIN diode driver is connected across the first RF bypass capacitor and a second PIN diode driver is connected across the second RF bypass capacitor.

In some aspects, the techniques described herein relate to a method, where the second PIN diode driver is a complementary PIN diode driver producing voltages and currents with opposite polarity than that of the first PIN diode driver.

In some aspects, the techniques described herein relate to a method, further including charging and discharging one or more of the first RF bypass capacitor, the series connected PIN diodes, and one or more capacitive elements in the RF circuitry from and to a power supply of a first resonant stage of a two-stage driver coupled across the first RF bypass capacitor.

In some aspects, the techniques described herein relate to a method, further including holding the reverse bias voltage across the series connected PIN diodes via a holding stage of the two-stage driver connected across the first RF bypass capacitor.

In some aspects, the techniques described herein relate to a method, further including supplying the current through the series connected PIN diodes via a holding stage of the two-stage driver connected across the first RF bypass capacitor.

In some aspects, the techniques described herein relate to a method, further including disconnecting at least one reactance element in an impedance matching network when the series connected PIN diodes are OFF.

In some aspects, the techniques described herein relate to a non-transitory, tangible computer readable storage medium, encoded with processor readable instructions to perform a method for switching two or more PIN diodes in and out of an impedance match network, the method including: supplying a current through the two or more PIN diodes to forward bias and turn the two or more PIN diodes ON, wherein RF circuitry is coupled between a reference node and an internal node, and a first RF bypass capacitor is connected between the first end of the two or more PIN didoes and the reference node, the internal node positioned between two of the two or more PIN diodes; and supplying a reverse bias voltage across the two or more PIN diodes to turn the two or more PIN diodes OFF. In some implementations of the non-transitory, tangible computer readable storage medium described above, a first impedance is presented to the RF circuitry when the two or more PIN diodes are ON, and a second impedance is presented to the RF circuitry when the two or more PIN diodes are OFF, wherein a magnitude of the second impedance is greater than a magnitude of the first impedance.

In some aspects, the techniques described herein relate to a non-transitory, tangible computer readable storage medium, wherein the supplying the reverse bias voltage includes supplying a first voltage to remove charges from an intrinsic region of each of the two or more PIN diodes; and supplying the reverse bias voltage to maintain the two or more PIN diodes OFF, wherein a magnitude of the first voltage is less than a magnitude of the reverse bias voltage.

These and other features, and characteristics of the present technology, as well as the methods of operation and functions of the related elements of structure and the combination of parts and economies of manufacture, will become more apparent upon consideration of the following description and the appended claims with reference to the accompanying drawings, all of which form a part of this specification, wherein like reference numerals designate corresponding parts in the various figures. It is to be expressly understood, however, that the drawings are for the purpose of illustration and description only and are not intended as a definition of the limits of the invention. As used in the specification and in the claims, the singular form of ‘a’, ‘an’, and ‘the’ include plural referents unless the context clearly dictates otherwise.

### BRIEF DESCRIPTION OF THE DRAWINGS

Various objects and advantages and a more complete understanding of the present disclosure are apparent and more readily appreciated by referring to the following detailed description and to the appended claims when taken in conjunction with the accompanying drawings:

FIG. 1A illustrates a schematic diagram of a dual supply PIN diode driver circuit driving a single PIN diode, in accordance with one or more implementations.

FIG. 1B illustrates another schematic diagram of a dual supply PIN diode driver circuit driving a single PIN diode, in accordance with one or more implementations.

FIG. 1C illustrates a schematic diagram of a PIN diode driver circuit driving a single PIN diode, in accordance with one or more implementations.

FIG. 2A illustrates a schematic diagram of an equivalent circuit for a PIN diode in the ON state, in accordance with one or more implementations.

FIG. 2B illustrates a schematic diagram of an equivalent circuit for a PIN diode in the OFF state, in accordance with one or more implementations.

FIG. 2C illustrates a schematic diagram of series connected PIN diodes, in accordance with one or more implementations.

FIG. 3A is a block diagram illustrating an example of a PIN diode driver driving two PIN diodes in series, where the two PIN diodes are in RF parallel, according to various aspects of the disclosure.

FIG. 3B is a block diagram illustrating an example of a PIN diode driver driving a plurality of strings of PIN diodes in series, where the strings of PIN diodes are in RF parallel, according to various aspects of the disclosure.

FIG. 3C is a block diagram illustrating an example of a plurality of PIN diode drivers driving a plurality of PIN diodes, where the plurality of PIN diodes are in series and in RF parallel, according to various aspects of the present disclosure.

FIG. 3D is a block diagram illustrating an example of a plurality of PIN diode drivers driving a plurality of strings of PIN diodes in series, where the plurality of strings of PIN diodes are in RF parallel, according to various aspects of the present disclosure.

FIG. 3E is a block diagram illustrating an example of a plurality of PIN diode drivers driving a plurality of PIN diodes in series, where the plurality of PIN diodes are in RF parallel, according to various aspects of the present disclosure.

FIG. 3F is a block diagram illustrating an example of a plurality of PIN diode drivers driving a plurality of strings of PIN diodes in series, where the plurality of strings of PIN diodes are in RF parallel, according to various aspects of the present disclosure.

FIG. 3G is a block diagram illustrating an example of a PIN diode driver driving a plurality of strings of PIN diodes in series, where the plurality of strings of PIN diodes are in RF parallel, according to various aspects of the disclosure.

FIG. 3H is a block diagram illustrating an example of a plurality of PIN diode drivers driving a plurality of strings of PIN diodes in series, where the plurality of strings of PIN diodes are in RF parallel, according to various aspects of the present disclosure.

FIG. 4A is a block diagram of a two-supply half bridge driver driving a plurality of PIN diodes, according to various aspects of the present disclosure.

FIG. 4B is a block diagram of a two-supply half bridge driver driving a plurality of strings of PIN diodes, according to various aspects of the present disclosure.

FIG. 5 illustrates an example of a two-stage driver driving a plurality of PIN diodes, according to various aspects of the present disclosure.

FIG. 6 illustrates an example of a two-stage driver for driving a plurality of PIN diodes, according to various aspects of the present disclosure.

FIG. 7 illustrates an example of a plurality of two-stage drivers for driving a plurality of PIN diodes, according to various aspects of the present disclosure.

FIG. 8 illustrates an example of a method for driving a plurality of PIN diodes, according to various aspects of the present disclosure.

FIG. 9 illustrates an example of a method for driving a plurality of PIN diodes using a plurality of PIN diode drivers, according to various aspects of the present disclosure.

FIG. 10A illustrates an example of a method for driving a plurality of PIN diodes using a plurality of PIN diode drivers, according to various aspects of the present disclosure.

FIG. 10B illustrates an example of a method for driving series connected PIN diodes in a PIN diode switch, according to various aspects of the present disclosure.

FIG. 11 illustrates a block diagram of a computer system that may be used to implement one or more aspects of the present disclosure.

### DETAILED DESCRIPTION

Prior to describing the embodiments in detail, it is expedient to define certain terms as used in this disclosure.

The word “exemplary” is used herein to mean “serving as an example, instance, or illustration.” Any embodiment described herein as “exemplary” is not necessarily to be construed as preferred or advantageous over other embodiments.

Preliminary note: the flowcharts and block diagrams in the following Figures illustrate the functionality and operation of possible implementations of a PIN diode switch in which two or more PIN diodes are driven in series by one or more PIN diode drivers while the two or more PIN diodes appear in parallel for RF current according to various embodiments of the present disclosure. It should be noted that, in some alternative implementations, the functions noted in each block may occur out of the order noted in the figures. For example, two blocks shown in succession may, in fact, be executed substantially concurrently, or the blocks may sometimes be executed in the reverse order, depending upon the functionality involved. For instance, the operations of connecting a second end of series connected PIN diodes to a reference node can be interchanged or performed concurrently with connecting a RF bypass capacitor between the reference node and a first end of series connected PIN diodes.

As used herein, the term “PIN diode” refers to any two-terminal device that acts like a PIN diode in the sense that it acts like a small resistor (e.g., less than 0.2 ohm) to RF current when forward biasing current flows through the device and acts like a small capacitor (e.g., less than 10 pF) to RF current when a reverse bias voltage is applied across the device.

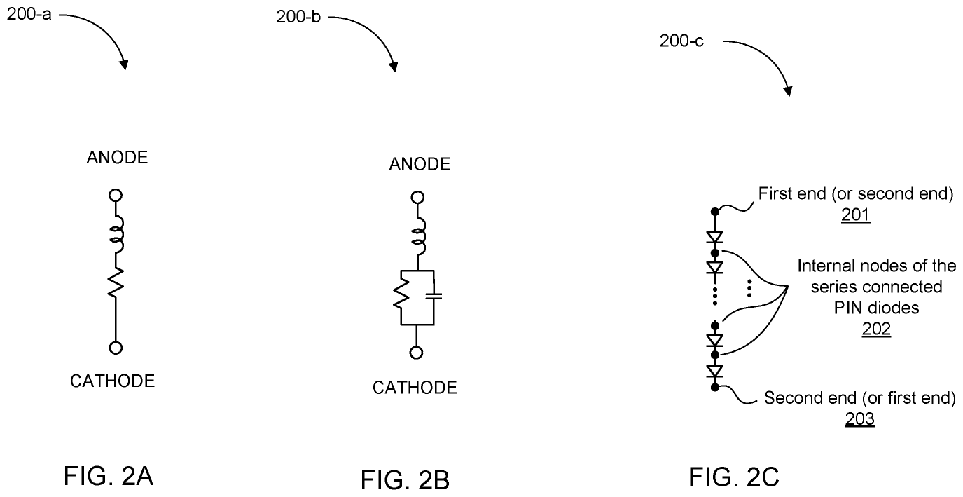

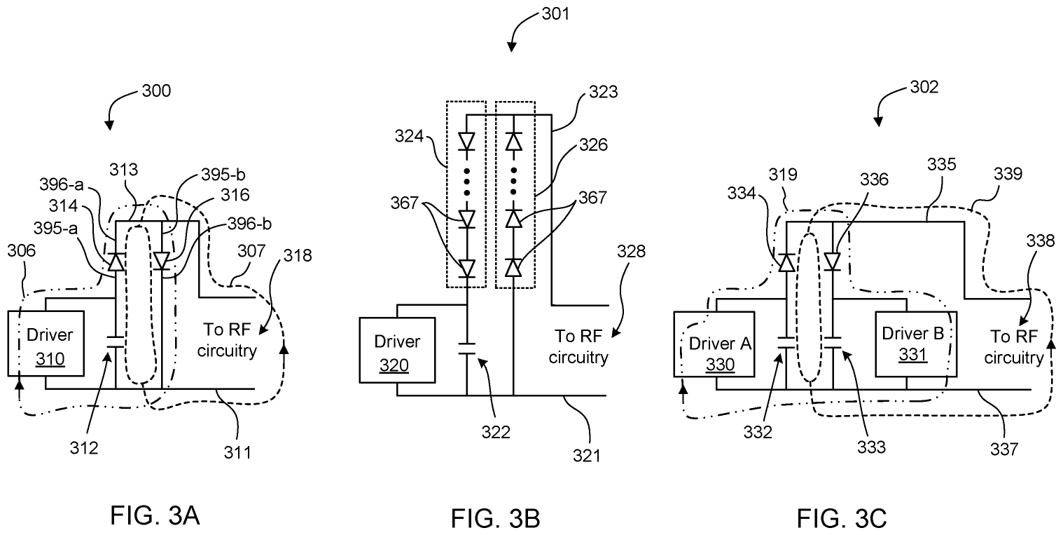

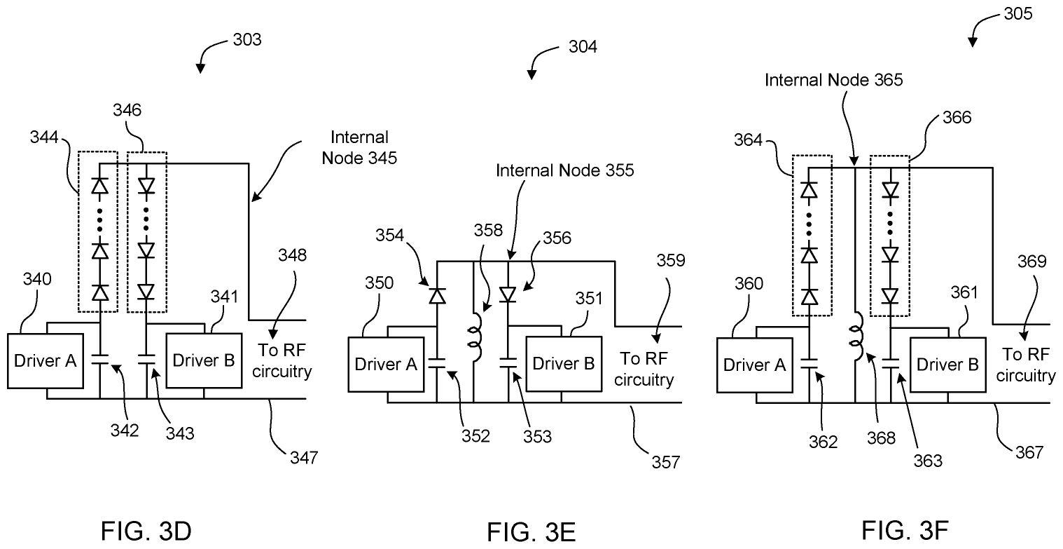

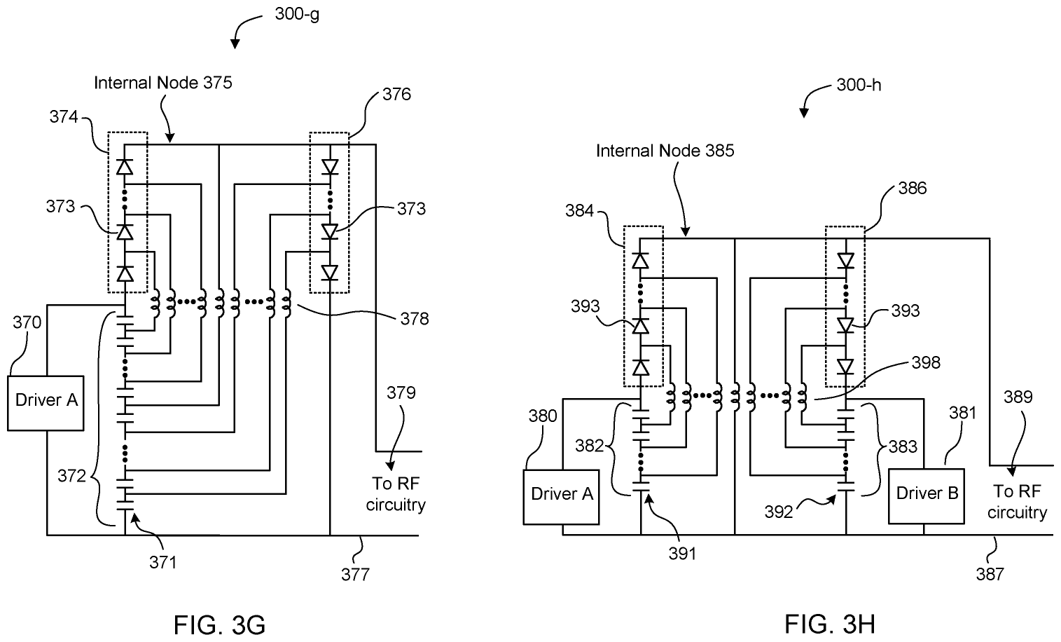

As used herein, the term “series connected PIN diodes”, such as series connected PIN diodes 200-c in FIG. 2C, refers to PIN diodes connected in series with the anode of one PIN diode connected to the cathode of the adjacent PIN diode as shown in FIG. 2C. The term “first end” 201 of series connected PIN diodes refers to either the anode or the cathode of either the last or the first PIN diode in the series connected PIN diodes. The term “second end” 203 of series connected PIN diodes refers to the anode or cathode of the last or first diode in the series connected PIN diodes that is not the “first end”. The term “internal node of the series connected PIN diodes” or “internal node”, such as internal nodes 202 in FIG. 2C, refers to any PIN diode anode to PIN diode cathode connection in the series connected PIN diodes 200-c. With one of the intermediary nodes (e.g., one of the internal nodes 202 in FIG. 2c) of the series connected PIN diodes chosen as “the internal node” (e.g., internal node 323 in FIG. 3B), the series connected PIN diodes are divided into two strings (e.g., PIN diode strings 324 and 326 of FIG. 3B) of series connected PIN diodes with one string consisting of all the PIN diodes between the “first end” and the “internal node” and the second string consisting of all the diodes between the “internal node” and the “second end”.

As used herein, the terms “diode strings” and “PIN diode strings” may be used interchangeably throughout the disclosure and may be used to refer to a plurality of PIN diodes connected in series (e.g., PIN diode string 324 in FIG. 3B comprises a plurality of PIN diodes 367 connected in series).

As noted earlier, a PIN diode is an electrical diode device with an un-doped or lightly doped intrinsic (I) semiconductor region sandwiched between a heavily doped p-type semiconductor region (P) and a heavily doped n-type semiconductor region (N); hence, the “PIN diode” designation. In general, PIN diodes obey conventional diode behavior for low frequency input signals. However, for higher frequency input signals (e.g., >10 MHz), PIN diodes operate as a small resistor in the forward biased or ON-state (e.g., as a 0.15-ohm resistor) and as a small capacitor (e.g., a 4 pF capacitor) in the reverse biased or OFF-state. As such, PIN diodes are often utilized in radio frequency (RF) applications, e.g., in attenuators and in fast switches, where high isolation and low loss are desired. In one particular implementation, PIN diodes are used in an impedance match network configured to match a changing (or varying) load impedance of a plasma load to a desired impedance (e.g., 50 ohm or 70 ohm, to name two non-limiting examples) so that a high-power RF generator can efficiently deliver power. In such an implementation, the PIN diodes serve to connect or disconnect reactive components, typically capacitors, of the impedance matching network to quickly alter the properties of the matching network by switching the reactive elements in and out of the network.

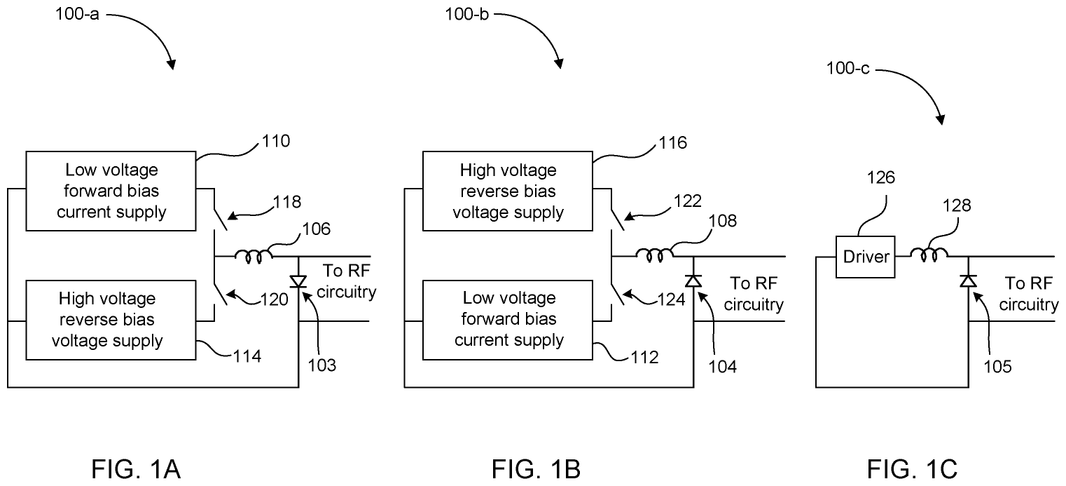

PIN diodes in a switching circuit typically have an accompanying PIN diode driver circuit or switch driver that provides a controlled forward bias current and a reverse bias voltage. For example, FIGS. 1A and 1B illustrate dual supply PIN diode driver circuits 100-a and 100-b, respectively. The dual supply PIN diode driver circuit 100-a comprises a PIN-type diode 103 connected to an RF circuit, while the dual supply PIN diode driver circuit 100-b comprises a PIN-type diode 104 connected to another RF circuit. Each PIN diode 103, 104 is driven by two power supplies (e.g., power supplies 110 and 114 for PIN diode driver circuit 100-a, and power supplies 112 and 116 for PIN diode driver circuit 100-b), which serve to provide a forward bias current and a reverse bias voltage to the respective PIN diodes 103, 104. For example, in the circuit 100-a, the low voltage forward bias current supply 110 is serially connected to a first switch 118, while the high voltage reverse bias voltage supply 114 is serially connected to a second switch 120. When the first switch 118 is closed (and second switch 120 is open), the forward bias current supply 110 provides a forward bias current to the PIN diode 103. Additionally, when second switch 120 is closed (and first switch 118 is opened), the reverse bias voltage supply 114 provides a reverse bias voltage across the PIN diode 103. Similarly, in circuit 100-b, a high voltage reverse bias voltage supply 116 is serially connected to a first switch 122 to provide a reverse bias voltage across the PIN diode 104 when first switch 122 is closed, and a low voltage forward bias current supply 112 is serially connected to a second switch 124 to provide a forward bias current to the PIN diode 104 when second switch 124 is closed. While FIGS. 1A and 1B show elements 106, 108 as inductors, it should be noted that any other element (or circuitry) that passes direct-current (DC) at low frequencies and suppresses the RF signal applied to the PIN diodes 103, 104 by the RF circuitry, may be utilized in different embodiments. Some non-limiting examples of the type of elements and/or circuits that may be utilized in lieu of inductors 106, 108 include an RF choke, a parallel resonant LC tank or tanks, a quarter wavelength (at the frequency of the applied RF signal) transmission line, etc.

FIG. 1C illustrates a schematic diagram of a PIN diode driver circuit 100-c comprising a driver 126, a PIN diode 105, RF circuitry connected to the PIN diode 105, and an inductor 128 (or another applicable element that passes DC at low frequencies and suppresses RF frequency applied to the PIN diode 105 by the RF circuitry), in accordance with one or more implementations. As seen, the driver 126 is used to drive the single PIN diode 105. Here, FIG. 1C represents a generalization of FIG. 1B. However, it should be noted that, reversing the polarity of the PIN diode 105 in FIG. 1C would represent a generalization of FIG. 1A. In a conventional PIN diode circuit, the PIN diode driver (e.g., driver 126) is placed in series with a RF blocking DC passing device, such as inductor 128. The series combination of the PIN diode driver (e.g., driver 126) and the RF blocking DC passing device, such as inductor 128, is connected across the PIN diode 105. The inductor 128 is used to isolate the driver 126 from high RF voltages that the RF circuitry may impose across the PIN diode 105. In a typical application, the RF blocking device (e.g., inductor 128) may see upwards of 1000 V RMS voltage at the RF frequency, e.g., 13.56 MHz. In such cases, the RF blocking device should be designed to have low RF losses when subjected to high RF voltage, and be able to handle high currents (e.g., above a pre-defined threshold, such as 5 A) when the PIN diode is toggled between the forward biased (ON state) and the reverse biased (OFF) state.

Operation of the PIN diode driver circuit is now described in greater detail, and again refers to circuit 100-a as an example. To forward bias the PIN diode 103, switch 118 is closed and switch 120 is open. The low voltage current supply 110 provides a forward bias current to the PIN diode 103. When the PIN diode 103 is forward biased, holes from the ‘P’ region material and electrons from the ‘N’ region material of the diode 103 are injected into the ‘I’ region material, where the ‘I’ region is sandwiched between (or adjacent each of or positioned between) the ‘P’ and the ‘N’ region materials. As the charges in the diode 103 do not recombine instantaneously, a net charge is stored in the ‘I’ region that decays exponentially if not continuously replenished, with a time constant known as the carrier lifetime. An amount of charge equal to the product of the forward biasing current and the carrier lifetime builds up in the intrinsic region. As long as the charge that any RF current flowing through the PIN diode can remove in one half of an RF cycle is significantly less than the stored charge, the PIN diode will conduct RF current in either direction and acts as a small resistor in the forward biased state. Thus, in some aspects, the PIN diode 103 acts as a resistor with an effective “ON” resistance value at RF frequency. An equivalent forward biased circuit 200-a for a PIN diode, such as PIN diode 103, is illustrated in FIG. 2A. A typical value for the resistor in FIG. 2A is 0.15 ohm and a typical value for the inductor in FIG. 2A is 1 nH, although other resistance and inductance values are contemplated in different embodiments.

To reverse-bias the PIN diode 103, switch 118 is opened and switch 120 is closed to provide a reverse bias voltage to the PIN diode 103 from the high voltage reverse bias voltage supply 114. During reverse-bias operation, the PIN diode 103 has an equivalent circuit (e.g., shown by equivalent reverse biased circuit 200-b in FIG. 2B) of a large resistor (i.e., larger by several factors than the resistance value in the equivalent forward biased circuit 200-a) shunted by a small capacitance. Typical capacitance, resistance, and inductance values for the circuit 200-b of FIG. 2B, e.g., at 13.56 MHz, may be around 4 pF for the capacitor, 1 megaohm for the resistor, and 1 nH for the inductor. By varying aspects of the PIN diode 103, a variety of forward-bias resistance and reverse-bias capacitance may be achieved for specific applications in various contexts.

One of the potential performance issues with conventional PIN diode circuits (e.g., PIN diode circuits 100-a, 100-b) is that the RF blocking device (e.g., inductors 106, 108, 128) may be bulky (large volume), contribute to RF losses, and allow high voltages to develop across the PIN diode when used in high speed, high repetition rate, and/or high-power applications. In some non-limiting examples, when a PIN diode is used in a high-power application with frequencies ranging from 3 to 30 MHz, the PIN diode may be forward biased with 1 ampere from the forward bias current supply and reverse biased with 1500 V from the reverse bias voltage supply. The carrier lifetime for a typical diode in such an application may be about 12 μs. To quickly (e.g., in a time period shorter than the carrier lifetime) switch from the forward biased (ON) state to the reverse biased (OFF) state, the charge to be removed from the PIN is based at least in part on the forward current and carrier lifetime (e.g., the product of the forward current and carrier lifetime). In the example referenced above, a charge of 12 μC may need to be removed to switch from the forward biased to the reverse biased state. If this charge is removed by the high voltage power supply (e.g., high voltage power supply 114 in FIG. 1A), the energy expended may be calculated as the product of the power supply voltage and the charge, i.e., 1500 V×12 μC=18 mJ. If this operation is performed at a high repetition rate, the power required can be prohibitive for many types of applications. For example, if the operation of the forward and reverse biasing of a PIN diode (e.g., PIN diode 103) is to be performed at a 10 kHz repetition rate, in this example, the power drawn from the high voltage power supply 114 may be calculated as 18 mJ×10 kHz=180 W. In one non-limiting example, an impedance matching network for matching a 3 kW RF generator to a load may contain 50 PIN diodes. If half of the PIN diodes in said impedance matching network each consume 180 W, total power consumption for the impedance matching network that matches the 3 kW RF generator to the load may be calculated as 25*180 W=4.5 kW. In some circumstances, the relatively high-power consumption of the impedance matching network undoes most of the benefit of having the impedance matching network in the first place. Furthermore, a substantial fraction (e.g., more than half) of the power drawn (e.g., ˜180 W) from the high voltage power supply 114 may be dissipated in the PIN diode during reverse recovery of the PIN diode which is more than what a typical PIN diode can safely dissipate.

To reduce the power expended in removing charge from the ‘I’ region, reactive circuit elements can be used to either reduce expended energy or recover stored energy. For instance, the inductors 106 and 108 in combination with the switches 118 and 120 (or switches 122 and 124) can be used to reduce expended energy or recover stored energy. In some circumstances, however, when reactive circuit elements are used, the PIN diode may snap off when the charge is being extracted from the ‘I’ region. This sudden turn-off of the PIN diode (or sudden reduction of the current through the PIN diode) may result in a high voltage drop (e.g., above the breakdown voltage of the PIN diode) across the PIN diode if it is being driven through an inductor (e.g., inductor 106 or inductor 108) as is typical for energy recovery, which can lead to PIN diode failure.

One solution to this high-power consumption and rapid turn-off and overvoltage of the PIN diode is using RF parallel DC series connected PIN diodes and a RF bypass capacitor across the PIN diode driver. In other words, two sets of series connected PIN diodes can be arranged to appear in series with the PIN diode driver, while these same two sets of series connected PIN diodes appear in parallel to the RF circuitry. At the same time, the arrangement of the RF bypass capacitor across the PIN diode driver, along with appropriate selection of its capacitance value, helps reduce the maximum RF voltage that can develop across the PIN diode driver, as compared to the prior art. By reducing the maximum RF voltage across the PIN diode driver, aspects of the present disclosure enable the DC passing RF blocking device (e.g., inductors 106, 108, 128) to be eliminated, or to be replaced by a RF blocking device handling a small fraction (e.g., 5%) of the RF voltage applied across the PIN diode. In addition to reducing or eliminating the likelihood of the PIN diode accidentally snapping off, the elimination of the DC passing RF blocking device (e.g., inductor 106) also allows for a more compact PIN diode switch or system (e.g., 300, 301, 302, 303, 304, 305, 400, 401). Additionally, the use of the RF bypass capacitor for blocking the PIN diode driver current (DC current), in combination with another DC blocking device (e.g., a series capacitor) in the RF circuitry, creates a DC current path that flows through the PIN diode driver and the series connected diodes. Both ends of the series connected PIN diodes are connected to the reference node with low RF impedance (through the RF bypass capacitor on one end and either directly or through a second RF bypass capacitor, if a second driver is used, on the other end) so neither end of the series connected PIN diodes can be disconnected at RF frequencies from the reference node by reverse biasing the PIN diodes, but an internal node of the series connected PIN diodes can be disconnected from the reference node by reverse biasing the PIN diodes. By connecting the rest of the RF circuitry between the internal node and the reference node, the circuit can function as an RF switch. The effect of connecting the RF circuitry between the internal node and the reference node is that the PIN diodes between the internal node and one end of the series connected diodes are in RF parallel to the PIN diodes connected between the internal node and the other end of the series connected PIN diodes.

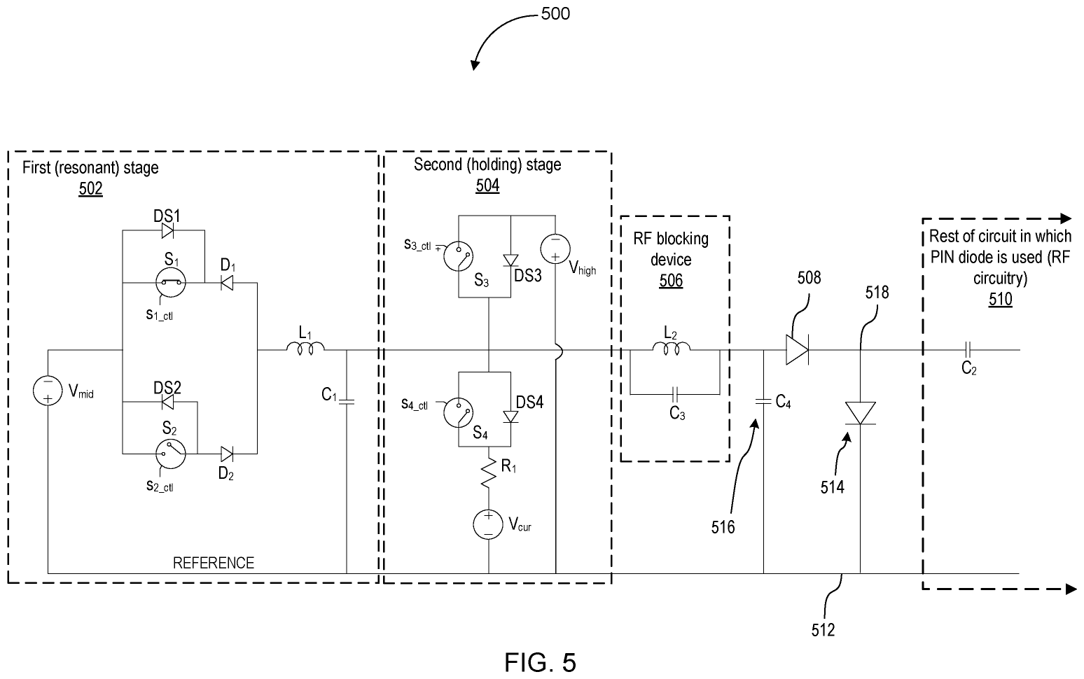

Additionally, or alternatively, a two-stage (or dual-stage) driver circuit comprising a resonant stage (e.g., shown as resonant stage 502 in FIG. 5) for energy recovery followed by a holding stage (e.g., shown as holding stage 504) may be employed to mitigate high-power consumption and rapid turn-off and overvoltage of the PIN diode seen in the prior art. Such a two-stage driver circuit simultaneously achieves: 1) fast switching; 2) energy recovery; and 3) avoidance of a dangerous voltage spike when the PIN diodes snap off. Using a first (resonant) stage followed by a second (holding) stage provides the ability to drive PIN diodes (e.g., PIN diodes 508, 514) at high speed without excessive power because energy is recovered in the system. The holding stage serves both to limit the voltage when the PIN diodes snap off, to hold the high reverse voltage, and supply the current in the ON state. In the process of limiting the voltage, energy is recovered to a high voltage supply (e.g., V_{high} in FIG. 5), in the holding stage, that is connected to the hold circuitry. Since the recovered energy generally exceeds the energy input to the system via the high-voltage supply, the excess recovered energy can be passed back to the resonant stage, optionally via a power converter (not shown in FIG. 5). This excess recovered energy can also be passed to other sources besides the resonant stage or dissipated as heat (though this is typically not desired).

FIG. 3A is a block diagram 300 illustrating an example of a PIN diode driver 310 driving two PIN diodes 314, 316 in series, where the two PIN diodes 314, 316 are in RF parallel, according to various aspects of the disclosure. FIG. 3A illustrates one non-limiting example of a PIN diode circuit (or PIN diode switch) that may be employed to avoid the need for a RF blocking DC passing device (e.g., inductor) between the PIN diode driver 310 and PIN diode(s). As seen in FIG. 3A, in some embodiments, a plurality of PIN diodes (2 in this example) may be connected such that they appear in series for the PIN driver current 306, but in parallel for RF current 307. In some examples, the RF circuitry (not shown in detail) may include a DC blocking device, typically a series capacitor (e.g., shown as capacitor, C₂, in RF circuitry 510 and/or 610 in FIGS. 5 and/or 6, respectively), which prevents DC current from flowing through the RF circuitry. In this way, the plurality of PIN diodes may appear in DC series to the driver 310 since the PIN driver current (i.e., DC current) is blocked from flowing through the RF bypass capacitor 312 and the RF circuitry (i.e., due to the DC blocking device, such as a series capacitor, in the RF circuitry). Additionally, there is minimal to no flow of RF current through the PIN diode driver 310, i.e., the combination of low voltage over the PIN diode driver 310 coupled with a relatively high impedance of the PIN diode driver 310 to RF current makes the RF current through the driver 310 negligible.

As used herein, the term “RF bypass capacitor” may refer to a capacitor that has sufficient capacitance (i.e., is large enough) to enable the RF voltage developed over the capacitor (e.g., when the maximum possible RF current is flowing through the capacitor) to be a small fraction (i.e., less than a pre-defined threshold) of the maximum RF voltage that may exist over the PIN diode switch. As an example, in a PIN diode switch where 1000V RMS RF voltage may be developed over the PIN diode switch, and a maximum RF current of 10 A RMS may flow through a RF bypass capacitor, the RF bypass capacitor may be selected such that the voltage drop across the RF bypass capacitor is less than 50 V RMS (e.g., less than 5% of the maximum RF voltage developed over the PIN diode switch). In this example, if the RF frequency is 13.56 MHz, the capacitance of the RF bypass capacitor may be selected to be at least 2.35 nF. In other words, the RF bypass capacitor can be selected such that

$$5 \% > \frac{{V}_{RF \_ Cap}}{{V}_{RF \_ PIN}} ,$$

where V_{RF_PIN} is a maximum RF voltage that may exist over the PIN diode switch and V_{RF_Cap} is the RF voltage developed over the RF bypass capacitor. In other embodiments,

$$10 \% > \frac{{V}_{RF \_ Cap}}{{V}_{RF \_ PIN}} , or 30 \% > \frac{{V}_{RF \_ Cap}}{{V}_{RF \_ PIN}} .$$

In the PIN switch block diagram 300 shown in FIG. 3A, two PIN diodes 314 and 316 are connected in series (herein referred to as series connected PIN diodes 314, 316), a RF bypass capacitor 312 is connected between a reference node 311 and a first end 395-a of the series connected PIN diodes 314, 316. Additionally, a second end 396-b of the series connected PIN diodes 314, 316 is connected to the reference node. In this example, RF circuitry 318 is connected between the reference node 311 and an internal node 313 between the series connected PIN diodes 314, 316, and a driver 310 is connected across the RF bypass capacitor 312. Alternatively, it can be said that the driver 310 is connected between the first end 395-a of the series connected PIN diodes 314, 316 and the reference node 311. Specifically, the RF circuitry 318 is connected between the reference node 311 and the internal node 313, where the internal node 313 is connected to one end of each of the PIN diodes 314, 316. Here, the internal node is connected to second end 396-a of the first PIN diode 314 and the first end 395-b of the second PIN diode 316. A first end of the first PIN diode 314 is also the first end 395-a of the series connected PIN diodes 314, 316 and the second end of the second PIN diode 316 is the second end 396-b of the series connected PIN diodes 314, 316.

By virtue of the design of the PIN switch shown in FIG. 3A, the PIN diode driver 310 is not subject to high RF voltages, which allows the traditional RF blocking device (e.g., shown as inductors 106, 108, and 128 in FIGS. 1A-1C) between the driver and PIN diode(s) to be eliminated, reduced in size, and/or drastically simplified. In this arrangement, the driver 310 is connected across the RF bypass capacitor 312. In one non-limiting example, the PIN diodes 314 and/or 316 may be designed to safely handle a maximum RF current of 10 A RMS. In this example, if the PIN diode switch is operating at 13.56 MHz and the capacitance of the RF bypass capacitor 312 is about 5 nF, the voltage developed across the RF bypass capacitor 312 is approximately 23V RMS when the PIN diode is conducting the maximum RF current of 10 A RMS that it can safely conduct. As can be appreciated, this RMS voltage (e.g., 23 V RMS) developed across the RF bypass capacitor 312 is small compared to the OFF-state RMS voltage (e.g., 1000 V RMS) that the PIN diode driver 310 may be subject to in a typical PIN diode switch circuit. As a result, the RF blocking device (e.g., inductor) between the driver 310 and PIN diode(s) can be eliminated.

While not necessary, in some examples, an RF filter may be employed to protect the driver 310 against the small RF voltage (e.g., 23V RMS) developed across the RF bypass capacitor 312. However, this RF filter (optional) can be significantly smaller than the RF blocking device (e.g., inductor) used in a conventional PIN diode switch circuit (e.g., described above in relation to FIGS. 1A-C). Due to its compact nature, this optional RF filter can also be incorporated in the driver circuit 310, in some embodiments. Alternatively, the RF blocking capacitor 312 may be placed in series with a small inductor so that the series combination of the RF blocking capacitor 312 and inductor is resonant at the RF frequency, which serves to further reduce the RF voltage across the driver 310. For instance, with a RF bypass capacitor of 5 nF and a RF frequency of 13.56 MHz the value of the inductor is 27 nH minus the parasitic inductance of the chosen 5 nF capacitor.

FIG. 3A also shows the current paths for the PIN diode driver current (current path 306, shown as the dashed-dotted line) and the RF current (current path 307, shown as the dashed line). As shown by the current path 306 through the PIN diode driver 310, the two PIN diodes 314 and 316 appear in series for PIN diode driver current. The PIN diode driver current in the direction drawn is the direction to forward bias the PIN diodes 314, 316. In some cases, current can also briefly flow in the opposite direction when the driver 310 switches the PIN diodes 314, 316 from the forward biased (ON) state to the reverse biased (OFF) state. Additionally, or alternatively, the current may increase (for a short duration) above the nominal forward bias ON state current when the driver 310 switches the PIN diodes 314, 316 from the reverse biased (OFF) state to the forward biased (ON) state. Compared to the RF current (shown by current path 307) which oscillates at the RF operating frequency, e.g., 13.56 MHz, the PIN diode driver current can be considered to be DC current. In such cases, the RF bypass capacitor 312 blocks, or substantially blocks, the PIN diode driver current. In some instances, the RF bypass capacitor 312 may not block all of the PIN diode driver current, for instance, when the driver 310 is switching the PIN diode between the ON and OFF states (e.g., when the driver 310 is charging and discharging one or more of the RF bypass capacitor 312, the PIN diode(s), and/or capacitors that are part of the RF circuitry 318).

The RF current path 307 through the RF circuitry 318 in FIG. 3A shows that the two diodes 314, 316 appear in parallel for the RF current. In some cases, the RF bypass capacitor 312 may cause the RF current to preferentially flow through diode 316 when the PIN diodes 314, 316 are in the ON state since the PIN diode ON state resistance is small compared to the impedance of the RF bypass capacitor 312. In some cases, an optional resonant inductor (not shown) may be placed in series with the RF bypass capacitor 312, which not only helps reduce the RF voltage across the driver, but also the RF current imbalance between the diode 316 and diode 314.

FIG. 3B is a block diagram 301 illustrating an example of a PIN diode driver 320 driving a plurality of strings 324, 326 of PIN diodes in series, where the strings of PIN diodes are in RF parallel, according to various aspects of the disclosure. As seen, each string of PIN diodes comprises a plurality of PIN diodes 367 arranged in series. Furthermore, the plurality (2 in this example) of strings of PIN diodes are arranged in series, similar to the two PIN diodes 314, 316 in FIG. 3A. The PIN diode switch of FIG. 3B shows that the PIN diodes 314 and 316 of the PIN diode switch in FIG. 3A can be replaced by diode strings 324 and 326 while preserving the basic characteristics of FIG. 3A. As compared to the arrangement in FIG. 3A, where the RF bypass capacitor is connected between the reference node and the anode of the series connected PIN diodes, in this example, the RF bypass capacitor 322 is connected between the reference node 321 and the cathode of the PIN diode string 324 (also described as a cathode of a last PIN diode in the string 324). Additionally, the anode of the PIN diode string 326 (also described as an anode of a first PIN diode in the string 326) is connected to the reference node 321. The different orientation of the PIN diodes in FIGS. 3A and 3B shows that either direction can be implemented throughout the embodiments of this disclosure without departing from the scope and spirit of the disclosure and without undue experimentation. For the sake of simplicity, most embodiments will be shown with the diode orientation shown in FIGS. 3A and 3C, though this does not preclude implementation of the orientation shown in FIG. 3B. The RF circuitry 328 is connected between the reference node 321 and an internal node 323 of the series connected PIN diode strings. Specifically, the RF circuitry 328 is coupled at one end to the reference node 321, and at another end to an internal node 323 between the PIN diode string 324 and the PIN diode string 326. In other words, the internal node 323 is connected to one end of each of the PIN diode strings 324 and 326.

FIG. 3C is a block diagram illustrating an example of a PIN diode switch 302, where the PIN diode switch 302 comprises a plurality of PIN diode drivers 330, 331 and a plurality of PIN diodes 334, 336, according to various aspects of the present disclosure. As seen, the plurality of PIN diode drivers 330, 331 are used to drive the plurality of PIN diodes, where the plurality of PIN diodes are in series (for the PIN diode driver current) and in parallel (for the RF current).

The PIN diode switch 302 of FIG. 3C uses two complementary drivers 330 and 331 together with two RF bypass capacitors 332 and 333. Such a design makes two parallel RF paths, one path through PIN diode 334 and RF bypass capacitor 332 and the other path through PIN diode 336 and RF bypass capacitor 333, these two RF paths being symmetric. Symmetric RF paths help minimize or reduce the possibility of high RF current imbalance through the two PIN diodes 334, 336. In this case, to ensure current balance, the RF bypass capacitors 332 and 332 may not be placed in series with resonant inductors. Instead, an optional RF filter may be incorporated in one or more of the drivers 330 and 331, for instance, to further protect the PIN diode drivers 330 and 331. In some cases, the impedance of this optional filter may be selected such that the impedance viewed from the RF bypass capacitor 332 or 333 is high compared to the impedance of the RF bypass capacitor at the RF frequency (e.g., 13.56 MHz).

As seen in FIG. 3C, the PIN diode driver current 319 flows through the PIN diode driver 330, PIN diode 334, PIN diode 336, and PIN diode driver 331. That is, the two PIN diodes 334 and 336 are in series for the PIN diode driver current 319. Furthermore, RF current 339 flows through the RF circuitry 338 and then splits into two parallel paths, where one RF current path comprises the series combination of the PIN diode 334 and the RF bypass capacitor 332, while the other RF current path comprises the series combination of the PIN diode 336 and the RF bypass capacitor 333. Thus, the two PIN diodes 334 and 336 are in parallel for the RF current 339.

The term complementary as it relates to the PIN diode drivers indicates that the two drivers produce voltages and currents of opposite polarity. For example, to forward bias the PIN diodes 334 and 336, driver 330 (i.e., driver A) produces a positive voltage with respect to the reference node 337 at the node connected to the PIN diodes. This causes positive current to flow from driver A from the node where driver A 330 connects to the PIN diodes towards the PIN diodes. Similarly, driver 331 (i.e., driver B) produces a negative voltage with respect to the reference node 337 at the node connected to the PIN diodes, which causes positive current to flow from the PIN diodes to driver B at the node where the PIN diodes connect to driver B 331.

FIG. 3D is a block diagram illustrating an example of a PIN diode switch 303, according to various aspects of the disclosure. Specifically, the block diagram in FIG. 3D illustrates a plurality of PIN diode drivers (e.g., PIN diode drivers 340, 341) driving a plurality of strings of PIN diodes (e.g., PIN diode strings 344, 346) in series, where the plurality of strings of PIN diodes are in RF parallel, according to various aspects of the present disclosure. The PIN diode switch 303 implements one or more aspects of the PIN diode switches described herein, including at least PIN diode switches 300, 301, and/or 302.

PIN diode switch 303 of FIG. 3D shows that the PIN diodes (e.g., PIN diodes 334, 336) of switch circuit 302 of FIG. 3C can be replaced by strings of PIN diodes 344 and 346 without altering the basic properties of switch 302.

In the PIN diode switch 303 of FIG. 3D, PIN diode strings 344, 346 are connected in series, a first RF bypass capacitor 342 is connected between a reference node 347 and a first end (anode) of the series connected PIN diodes (i.e., all the PIN diodes in strings 344 and 346), a second RF bypass capacitor 343 is connected between the reference node 347 and a second end (cathode) of the series connected PIN diodes (i.e., all the PIN diodes in strings 344 and 346), RF circuitry 348 is connected between the reference node 347 and an internal node 345 of the series connected PIN diodes (i.e. all the PIN diodes in strings 344 and 346), and a first PIN diode driver 340 is connected across the first RF bypass capacitor 342 and a second or complementary PIN diode driver 341 is connected across the second RF bypass capacitor 343. In some cases, the first PIN diode driver 340 (or driver A) and second PIN diode driver 341 (or driver B) may be complementary, meaning that they produce voltages and currents of opposite polarity.

FIG. 3E is a block diagram illustrating an example of a PIN diode switch 304, according to various aspects of the disclosure. In this example, a plurality of PIN diode drivers 350, 351 are used to drive a plurality of PIN diodes, where the plurality of PIN diodes 354, 356 appear in series for the PIN diode driver current and in RF parallel (i.e., in parallel for the RF current), in accordance with one or more implementations.

As seen in FIG. 3E, a RF blocking DC passing circuit or device 358 is connected between an internal node 355 of the series connected PIN diodes (e.g., a node between the series connected PIN diodes 354 and 356) and a reference node 357. Additionally, RF circuitry 359 is also connected between the internal node 355 and the reference node 357. In some examples, and as depicted in FIG. 3E, the RF blocking DC passing device 358 (hereinafter the “RF blocking device 358”) may be an inductive device such as an inductor, although other types of circuits or devices are also contemplated in different embodiments. For example, a parallel combination of an inductor and capacitor, or a quarter wave transmission line may be utilized in lieu of an inductor in some embodiments. As noted above, this RF blocking device 358 (e.g., an inductor) may be configured to withstand the same RF voltage as the RF blocking devices 106, 108, and 128 described in relation to FIG. 1. However, the RF blocking device 358 may be simpler to design (e.g., less bulky) since it does not have to conduct the peak driver currents and/or peak forward bias currents. The addition of the RF blocking device 358 helps compensate for differences (or minor variations) between PIN diodes 354 and 356. As an example, when switching from the forward biased ON state to the reverse biased OFF state, if diode 354 recovers (meaning all charge is removed from the intrinsic or ‘I’ region of the PIN diode) before diode 356, a high, potentially damaging, voltage (e.g., voltage above a safety threshold) may develop across diode 354 and diode 356 may remain in a partially recovered state if no RF blocking device 358 is employed. Some aspects of the present disclosure are directed to mitigating the effects of such a scenario through the use of an RF blocking device 358 (or RF choke), such as an inductor. In such cases, RF blocking device 358 allows both PIN diodes 354 and 356 to recover to a fully off state more quickly and reduces the voltage spike that would otherwise develop over the PIN diode that recovers first, based at least in part on its DC passing and RF blocking characteristics.

FIG. 3F is a block diagram illustrating an example of a PIN diode switch 305, according to various aspects of the disclosure. In this example, the PIN diode switch 305 comprises a plurality of PIN diode drivers 360, 361 driving a plurality of strings of PIN diodes (e.g., PIN diode strings 364, 366), where the PIN diode strings appear in series (for PIN diode driver current) and in RF parallel (for RF current).

PIN diode switch circuit 305 of FIG. 3F shows that the PIN diodes (e.g., PIN diodes 354, 356) of switch circuit 304 can be replaced by strings of PIN diodes 364 and 366 without altering the basic properties of switch 304. In switch circuit 305, an RF blocking device 368, such as an inductor, can be utilized to compensate for differences (if any) between PIN diode strings 364 and 366.

In PIN diode switch circuit 305 of FIG. 3F, PIN diode strings 364 and 366 are connected in series, a first RF bypass capacitor 362 is connected between a reference node 367 and a first end (anode) of the PIN diode string 364, a second RF bypass capacitor 363 is connected between the reference node 367 and a second end (cathode) of the PIN diode string 366, RF circuitry 369 is connected between the reference node 367 and an internal node 365 of the PIN diode strings 364 and 366, a PIN diode driver 360 is connected across the first RF bypass capacitor 362, a complementary PIN diode driver 361 is connected across the second RF bypass capacitor 363, and a DC passing RF blocking device or circuit 368 (e.g., an inductor) is connected between the internal node 365 and the reference node 367. FIG. 3G is a block diagram 300-g illustrating an example of a PIN diode driver 370 driving a plurality of strings 374, 376 of PIN diodes in series, where the strings of PIN diodes are in RF parallel, according to various aspects of the disclosure. As seen, each string of PIN diodes comprises a plurality of PIN diodes 373 arranged in series. RF circuitry 379 is connected between a reference node 377 and an internal node 375 of the series connected PIN diode strings 374, 376. An RF bypass capacitor assembly 372, comprising a plurality of capacitors 371 connected in series, is connected between a first end of the series connected PIN diodes 373 and the reference node 377. A plurality of DC passing and RF blocking devices 378 (e.g., inductors, parallel combinations of inductors and capacitors, and quarter RF wavelength long transmission lines) connect between intermediary nodes of the series connected capacitors 371 and intermediary nodes of the series connected PIN diodes 373. The capacitors 371 may be shunted by large resistors (e.g., 10 megaohm resistors, not shown) to ensure that the voltage over the capacitors 371 remain balanced at DC, or additional drivers (not shown) may be connected between reference node 377 and the intermediary nodes of the series connected capacitors 371 to maintain balanced DC voltages over the capacitors 371. This arrangement of capacitors 371 and DC passing RF blocking devices 378 compensates for differences in the properties of the PIN diodes 373. If, e.g., during reverse biasing of the PIN diodes 373, one of the PIN diodes 373 turns off before another of the PIN diodes 373, current can flow through the DC passing RF blocking devices 378 to turn off the rest of the PIN diodes 373.

FIG. 3H is a block diagram 300-h illustrating an example of a plurality of PIN diode drivers 380, 381 driving a plurality of strings 384, 386 of PIN diodes in series, where the strings of PIN diodes are in RF parallel, according to various aspects of the disclosure. As seen, each string of PIN diodes comprises a plurality of PIN diodes 393 arranged in series. RF circuitry 389 is connected between a reference node 387 and an internal node 385 of the series connected PIN diode strings. A first RF bypass capacitor assembly 382, comprising a plurality of capacitors 391 connected in series, is connected between a first end of the series connected PIN diodes 393 and the reference node 387. A plurality of DC passing and RF blocking devices 398 (e.g., inductors, parallel combinations of inductors and capacitors, and quarter RF wavelength long transmission lines) connect between intermediary nodes of the series connected capacitors 391 and intermediary nodes of the series connected PIN diodes 393. A second RF bypass capacitor assembly 383, comprising of a plurality of capacitors 392 connected in series, is connected between a second end of the series connected PIN diodes 393 and the reference node 387. A plurality of DC passing and RF blocking devices 398 connect between intermediary nodes of the series connected capacitors 392 and intermediary nodes of the series connected PIN diodes 393. One of the DC passing and RF blocking devices 398 may be connected between the internal node 385 and the reference node 387. The capacitors 391 and 392 may be shunted by large resistors (e.g., 10 megaohm resistors) to ensure that the voltages over the capacitors 391 and 392 remain balanced at DC, or additional drivers (not shown) may be connected between reference node 387 and the intermediary nodes of the series connected capacitors 391 and 392 to maintain balanced DC voltages over the capacitors 391 and 392. This arrangement of capacitors 391 and 392 and DC passing RF blocking devices 398 compensates for differences in the properties of the PIN diodes 393. If, e.g., during reverse biasing of the PIN diodes 393, one of the PIN diodes 393 turns off before another of the PIN diodes 393, current can flow through the DC passing RF blocking devices 398 to turn off the rest of the PIN diodes 393.

In some circumstances, shifts in DC voltage can damage equipment (e.g., network analyzers) connected to circuits incorporating PIN diode switches (e.g., PIN diode matching networks). An advantage of the PIN switch circuits 302, 303, 304, 305, and 300-h of FIGS. 3C, 3D, 3E, 3F, and 3H, respectively, that use complementary drivers, is that because the drivers are complementary, the respective internal nodes 335, 345, 355, 365, and 385 remain at 0 volts with respect to the respective reference nodes, 337, 347, 357, 367, and 387 except for small disturbances because of non-identical PIN diodes and PIN diode drivers. This means that the RF circuit is not subjected to shifts in the DC voltage. Thus, aspects of the present disclosure help prevent the DC voltage at the internal nodes (e.g., nodes between adjacent PIN diodes or PIN diode strings) from drifting/straying with respect to the DC voltage at the reference nodes, which can adversely impact RF circuit performance and/or cause damage to sensitive equipment.

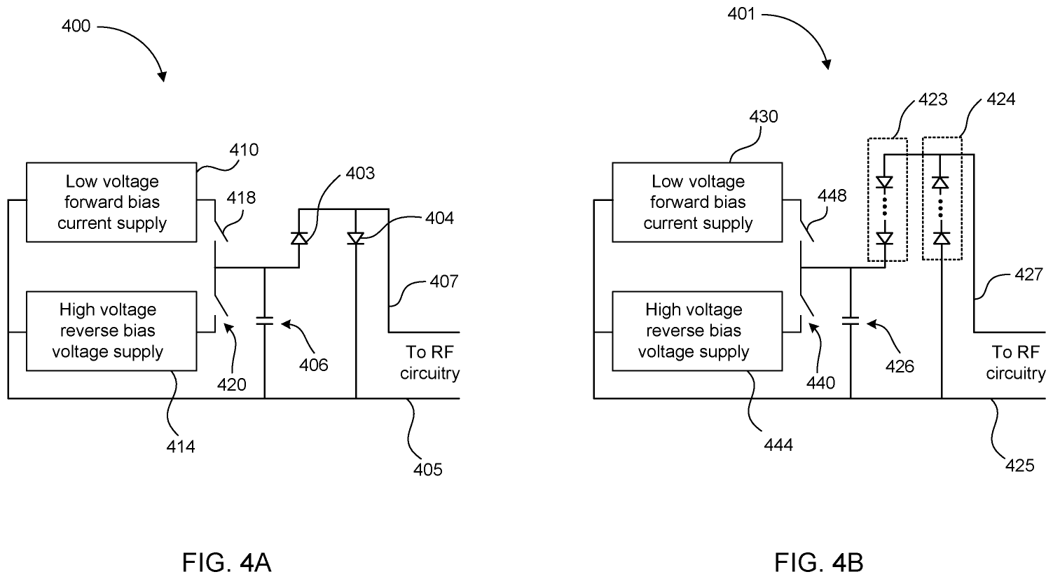

FIG. 4A is a block diagram 400 of a two-supply half bridge driver driving a plurality of PIN diodes 403, 404, according to various aspects of the present disclosure. Specifically, but without limitation, the PIN diode switch in FIG. 4A shows a particular implementation of the PIN diode switch previously described in relation to FIG. 3A. As seen, FIG. 4A depicts a 2-supply PIN diode driver consisting of a low voltage forward bias current supply 410, a high voltage reverse bias power supply 414, and two switches 418 and 420 arranged as a half-bridge circuit, in place of the driver 310.

FIG. 4B is a block diagram 401 of a two-supply half bridge driver driving a plurality of strings of PIN diodes (e.g., shown as PIN diode strings 423, 424), according to various aspects of the present disclosure. Specifically, but without limitation, the PIN diode switch of FIG. 4B shows a particular implementation of switch 301 of FIG. 3B. In FIG. 4B, a 2-supply PIN diode driver is used to implement the driver 320 of PIN diode switch 301, where the 2-supply PIN diode driver comprises a low voltage forward bias current supply 430, a high voltage reverse bias power supply 444, and two switches 448 and 440 arranged as a half-bridge circuit.

FIG. 5 illustrates an example of a PIN diode switch 500, according to various aspects of the disclosure. Here, the PIN diode switch 500 comprises a two-stage driver driving a plurality of PIN diodes. Specifically, but without limitation, the PIN diode switch 500 of FIG. 5 shows an example implementation of switch 300 of FIG. 3A. In one non-limiting example, the driver 310 of PIN diode switch 300 may be implemented as a two-stage driver consisting of a first resonant stage 502 and a second holding stage 504. As seen, the PIN diode switch 500 comprises the first (resonant) stage 502, the second (holding) stage 504, a RF blocking device 506 comprising an inductor (L₂) and a capacitor (C₃) arranged in parallel, a bypass capacitor 516 (C₄) coupled at one end to the RF blocking device 506 and at another end to a reference node 512, a first PIN diode 508, a second PIN diode 514, and an internal node 518. As seen, the RF circuitry 510 comprises at least one capacitor (C₂) and the RF circuitry 510 is coupled between the internal node 518 and the reference node 512. In this example, the capacitor (C₂) of the RF circuitry 510 is coupled to the internal node 518 between the PIN diode 508 and the PIN diode 514. In some examples, a power supply (shown as V_{mid} in the resonant stage 502) may charge and discharge one or more of the RF bypass capacitor 516, PIN diodes 508, 518, capacitor C₁ in the resonant stage 502, and any other capacitors that are part of the RF circuit 510. Because the capacitors are charged and discharged from the same voltage (e.g., V_{mid}), it is theoretically possible to do so without consuming power. However, some power (although minimal) is lost in the process due to nonideal switches. Additionally, or alternatively, some power is also lost in the PIN diodes 508, 518 during reverse recovery of the PIN diodes 508, 518.

In one non-limiting example, V_{mid}=1300 V (or −1300 V if the polarity is reversed in FIG. 5); V_{high}=3000 V (or −3000 V if the polarity is reversed in FIG. 5); L₁=100 μH; C₁=5 nF; C₂=60 pF; L₂=1.5 μH; C₃=22.96 pF; and C₄=5 nF, although other values are also contemplated in different embodiments and the example values listed herein are not intended to be limiting.

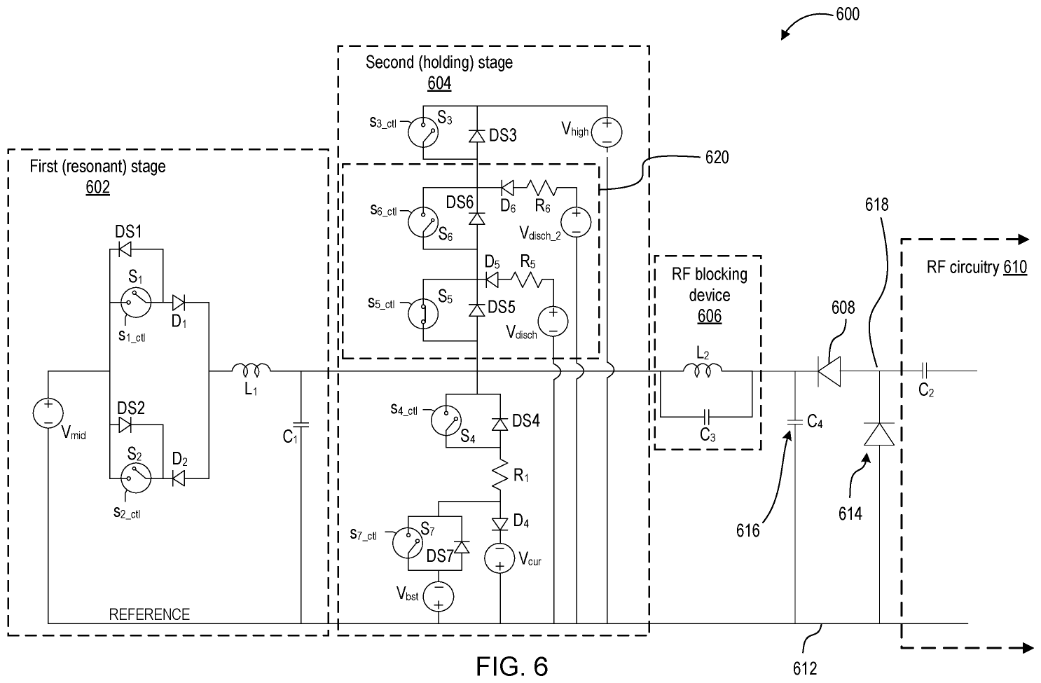

FIG. 6 illustrates an example of a PIN diode switch 600, according to various aspects of the disclosure. Here, the PIN diode switch 600 utilizes a two-stage driver for driving a plurality of PIN diodes and includes low voltage reverse bias power supplies and associated switches 620 in addition to a first (resonant) stage 602 and a second (holding) stage 604. In some embodiments, in switching from the ON to the OFF state, the PIN diode is first reverse biased with smaller reverse bias voltages, i.e., after disconnecting the forward bias supply (by opening S4 in the holding stage 604) and before operating the first (resonant) stage 602. This helps reduce the energy used to switch the PIN diode from the ON to the OFF state, for instance, by removing the charge from the PIN diode at low voltage. It should be noted that, the polarity of the PIN diodes in FIG. 6 are reversed as compared to those shown in FIG. 5.

FIG. 6 also serves to illustrate (by comparing to FIG. 5) that in order to construct a PIN diode switch in which the polarity of the PIN diodes are reversed, the voltages of the supplies in the PIN diode driver as well as the polarity of the switches in the PIN diode driver are also reversed. For example, switches (including diodes) that can hold off voltage of one polarity (i.e., conduct only a small current e.g., 1 microampere if a voltage of that polarity is applied) may be replaced by switches that can hold off voltage of the opposite polarity. Controlled switches, such as, but not limited to, field effect transistors (FETs) can only hold off voltage in the OFF state. In other words, for controlled switches, holding off a voltage of a certain polarity implies holding off a voltage of that polarity in the OFF state.

In one non-limiting example, V_{mid}=1400 V; V_{high}=3000 V; L₁=100 μH; C₁=5 nF; C₂=60 pF; L₂=1.5 μH; C₃=22.96 pF; and C₄=5 nF, although other values are also contemplated in different embodiments and the example values listed herein are not intended to be limiting.

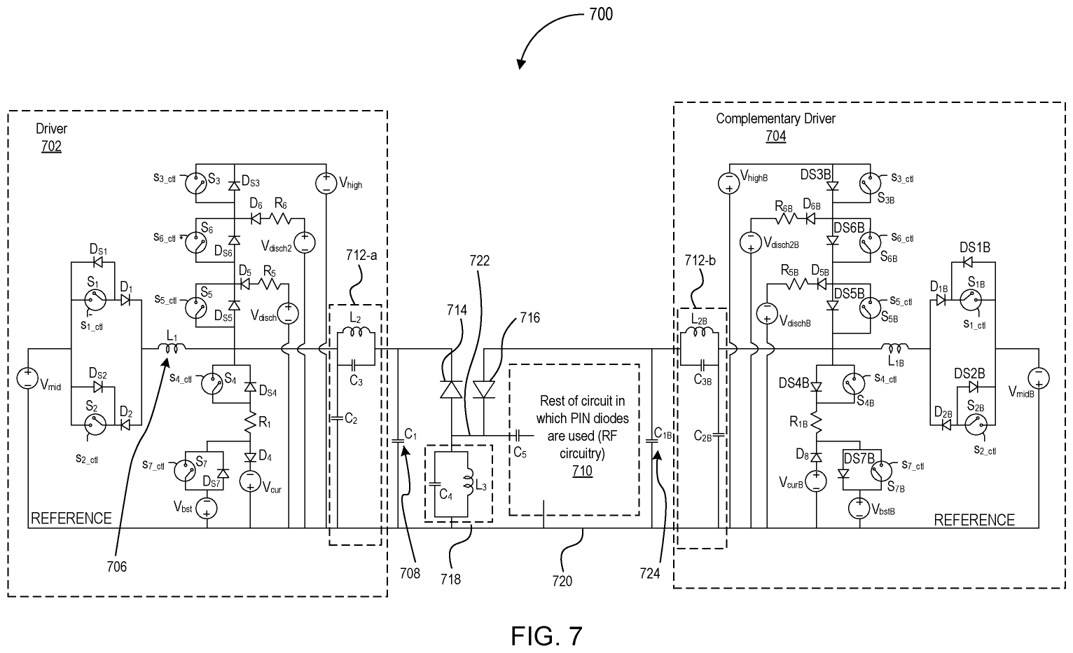

FIG. 7 illustrates an example of a PIN diode switch 700, according to various aspects of the disclosure. In this example, the PIN diode switch 700 employs a plurality of two-stage drivers (e.g., PIN driver 702, complementary PIN driver 704) for driving a plurality of PIN diodes (e.g., PIN diodes 714, 716). In some aspects, the PIN diode switch 700 of FIG. 7 is one example implementation of the PIN diode switch 304 of FIG. 3E using complementary PIN diode drivers. As seen, PIN diode switch 700 comprises a first driver 702 (e.g., similar or substantially similar to driver 351 or driver B in FIG. 3E), a second or complementary driver 704 (e.g., similar or substantially similar to driver 350 or driver A in FIG. 3E), an RF blocking device 718 (also shown as RF blocking device 358), RF bypass capacitor 708 (also shown as RF bypass capacitor 353), and a RF bypass capacitor 724 (also shown as RF bypass capacitor 352). In this implementation, each of the drivers 702 and 704 include RF filters (shown as RF filters 712-a and 712-b, respectively) in the driver. Additionally, the driver 702 includes a resonant circuit consisting of an inductor (L₁) 706 as well as the RF bypass capacitor (C₁) 708 and elements in the RF filter 712-a that enable the driver 702 to charge and discharge the capacitor 708, the PIN diodes 714 and 716, and other capacitances in the RF circuitry 710 from the same power supply (e.g., V_{mid} in driver 702). As seen, the complementary driver 704 contains similar resonant circuitry as the driver 702. For example, the complementary driver 704 includes a resonant circuit consisting of an inductor (L_{1B}), a RF bypass capacitor 724 (C_{1B}), and elements in the RF filter 712-b that enable the complementary driver 704 to charge and discharge the capacitor 724, the PIN diodes 714 and 716, and other capacitances in the RF circuitry 710 from the power supply (e.g., V_{midB} in complementary driver 704).

Capacitor C₂ provides a low impedance to RF current, which enhances the effectiveness of the RF filter 712-a. Furthermore, capacitor C₂ together with L₁ (706) and C₁ (708) (and to a smaller extent L₂ and C₃) forms part of the resonant circuit of the first resonant stage of driver 702. Similarly, capacitor C_{2B} together with L_{1B} and C_{1B} (724) (and to a smaller extent L_{2B} and C_{3B}) forms part of the resonant circuit of the first resonant stage of complementary driver 704. In some examples, capacitor C_{2B} is selected so as to provide a low impedance to RF current, which serves to enhance the effectiveness/performance of RF filter 712-b.

In one non-limiting example, V_{mid}=700 V; V_{high}=1500 V; L₁ and L_{1B}=100 μH; C₁ and C_{1B}=5 nF; C₂ (of RF filter 712-a)=1 nF; C₅ (of RF circuitry 710)=60 pF; C_{2B}=1 nF; L₂ and L_{2B}=1.5 μH; C₃ and C_{3B}=22.96 pF; C₄=4.3 pF; L₃=8 μH; V_{highB}=1500 V (−1500V if polarity is reversed in FIG. 7); and V_{midB}=700 V (−700 V if polarity is reversed in FIG. 7B), although other values are also contemplated in different embodiments and the example values listed herein are not intended to be limiting.

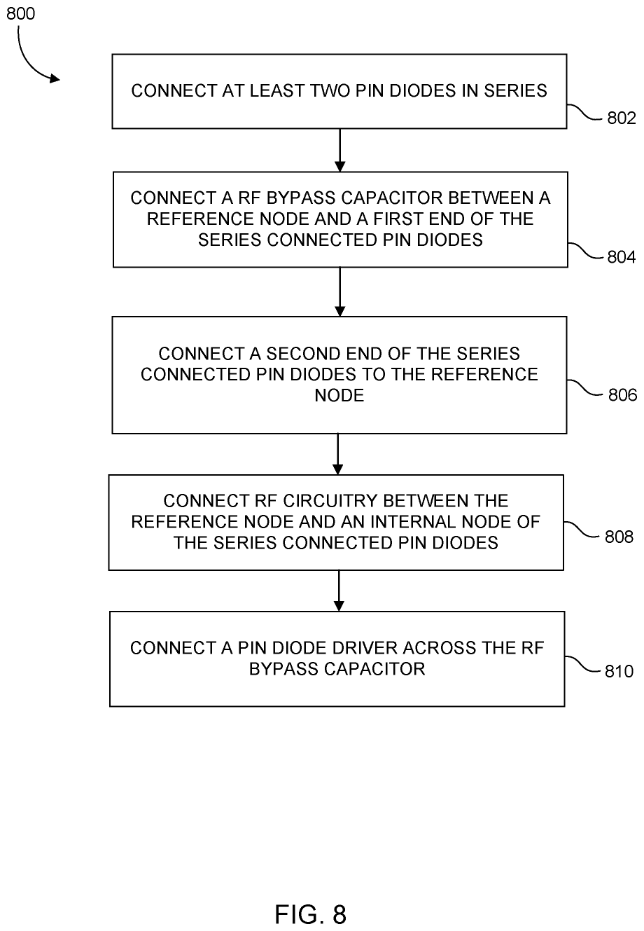

FIG. 8 shows an example of a method 800 for operating a PIN diode switch (e.g., PIN diode switches described in relation to FIGS. 3A-7), according to various aspects of the disclosure. The method 800 starts with connecting at least two PIN diodes in series (operation 802). Next, an RF bypass capacitor is connected between a reference node and a first end of the series connected PIN diodes (operation 804). In some examples, at operation 806, a second end of the series connected PIN diodes is connected to the reference node. Furthermore, operation 808 comprises connecting RF circuitry between the reference node and an internal node of the series connected PIN diodes. Lastly, a PIN diode driver is connected across the RF bypass capacitor (operation 810).

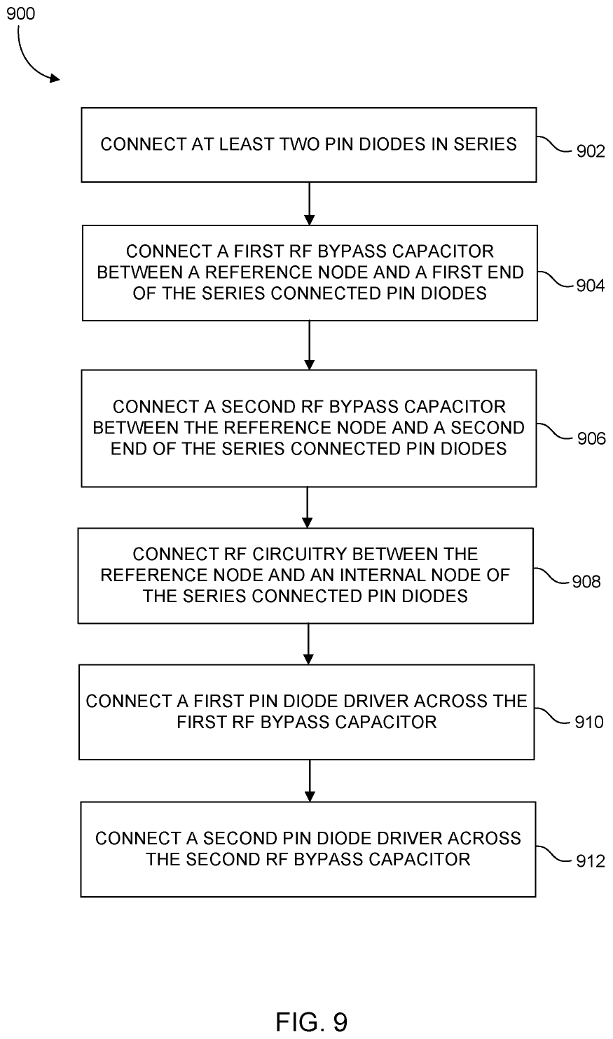

FIG. 9 shows an example of a method 900 for operating a PIN diode switch (e.g., PIN diode switches described in relation to FIGS. 3A-7), according to various aspects of the disclosure. The method 900 starts with connecting at least two PIN diodes in series (operation 902). At operation 904, the method 900 comprises connecting a first RF bypass capacitor between a reference node and a first end (e.g., anode) of the series connected PIN diodes (operation 904). In some embodiments, operation 906 comprises connecting a second RF bypass capacitor between the reference node and a second end (e.g., cathode) of the series connected PIN diodes. In some cases, RF circuitry is connected between the reference node and an internal node of the series connected PIN diodes (operation 908). Next, at operation 910, a first PIN diode driver is connected across the first bias capacitor. Additionally, at operation 912, a second or complementary PIN diode driver is connected across the second RF bypass capacitor. As noted above, two PIN diode drivers are said to be “complementary” when they generate currents and voltages of opposite polarity. For example, in FIG. 3D, PIN diode driver 340 (driver A) and PIN diode driver 341 (driver B) are complementary, implying that drivers A and B produce currents and voltages that are opposite in polarity. In some examples, using complementary PIN diode drivers helps prevent the DC voltage at the internal node (e.g., internal node 345) from drifting or straying from the DC voltage at the reference node (e.g., reference node 347).

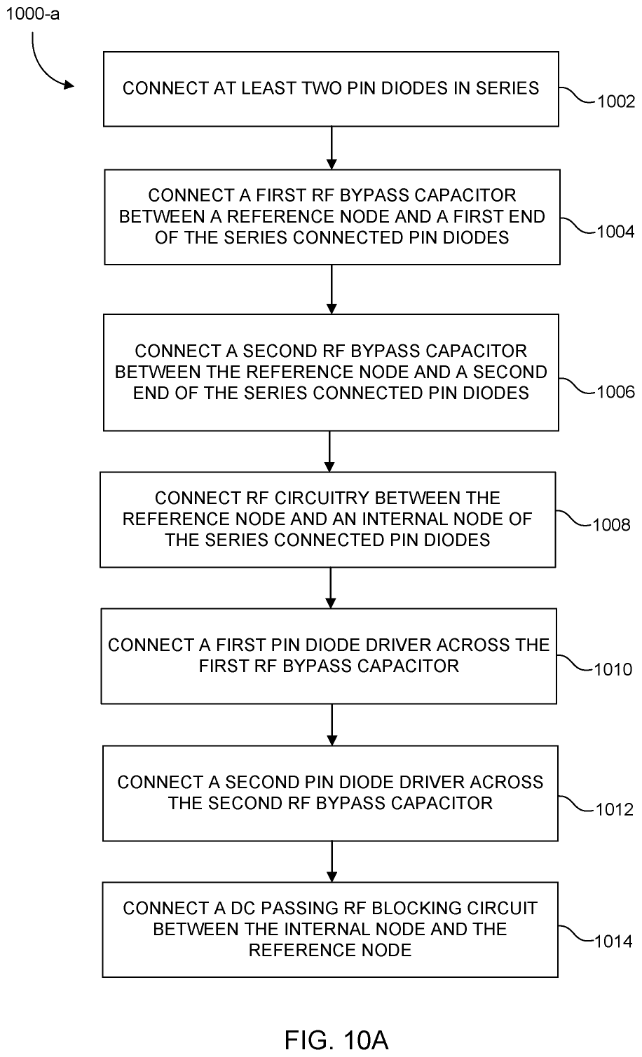

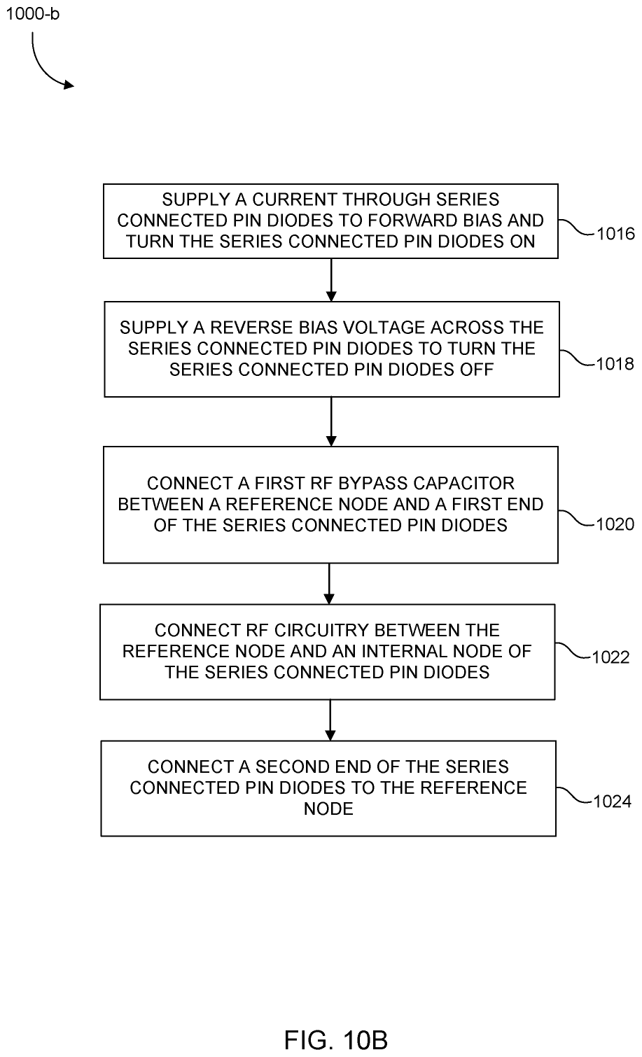

FIG. 10A shows an example of a method 1000-a for operating a PIN diode switch, according to various aspects of the present disclosure. The method 1000-a starts with connecting at least two PIN diodes in series (operation 1002). Next, a first RF bypass capacitor (e.g., first RF bypass capacitor 362 in FIG. 3F) is connected between a reference node (e.g., reference node 367) and a first end of the series connected PIN diodes (operation 1004). Next, a second RF bypass capacitor (e.g., second RF bypass capacitor 363) is connected between the reference node and a second end of the series connected PIN diodes (operation 1006). At operation 1008, RF circuitry (e.g., RF circuitry 369) is connected between the reference node and an internal node (e.g., internal node 365) of the series connected PIN diodes (operation 1008). Next, a PIN diode driver (e.g., Driver A in FIG. 3F) is connected across the first bias capacitor (operation 1010). Further, a complementary PIN diode driver (e.g., Driver B in FIG. 3F) is connected across the second RF bypass capacitor (operation 1012). In some cases, operation 1014 comprises connecting a DC passing RF blocking circuit or device (e.g., inductor 368) between the internal node and the reference node (operation 1014).

In terms of applications, when the DC series RF parallel PIN diode switch (e.g., PIN diode switches described in relation to any of FIGS. 3A-7) is implemented in connection with a solid-state match, multiple PIN diodes may be switched within the time window of a pulse (a power state) of an RF generator. In one non-limiting example, it is contemplated that a solid-state match implemented in connection with a PIN diode switch (e.g., PIN diode switch 301 in FIG. 3B, PIN diode switch 305 in FIG. 3F, etc.) may tune to states down to 50 microseconds in duration by enabling the PIN diodes (or PIN diode strings) to switch between the OFF and ON states in 10 microseconds or less.

FIG. 10B shows an example of a method 1000-b for driving series connected PIN diodes in a PIN diode switch, according to various aspects of the present disclosure. Additionally, or alternatively, FIG. 10B relates to a method for switching two or more PIN diodes in and out of an impedance match network, according to various aspects of the disclosure.

In some cases, the series connected PIN diodes comprise two or more PIN diodes connected in series between a first end and a second end. Operation 1016 comprises supplying a current through the series connected PIN diodes to forward bias and turn the series connected PIN diodes ON. Operation 1018 comprises supplying a reverse bias voltage across the series connected PIN diodes to turn the series connected PIN diodes OFF. Operation 1020 comprises connecting a first RF bypass capacitor between a reference node and a first end of the series connected PIN diodes. Operation 1022 comprises connecting RF circuitry between the reference node and an internal node of the series connected PIN diodes. Operation 1024 comprises connecting a second end of the series connected PIN diodes to the reference node. In some examples, when the two or more PIN diodes are ON, a first impedance is presented to the RF circuitry, and when the two or more PIN diodes are OFF, a second impedance is presented to the RF circuitry. In some cases, a magnitude of the second impedance is greater than a magnitude of the first impedance.

It should be noted that the operations 1016-1024 shown and described in relation to FIG. 10B need not occur in the order shown. For example, two or more operations (e.g., operations 1020, 1022, 1024) shown in succession may, in fact, be executed substantially concurrently. Additionally, or alternatively, the operations may be executed in the reverse order (e.g., operations 1020, 1022, and 1024 may be executed prior to operations 1016 and 1018).

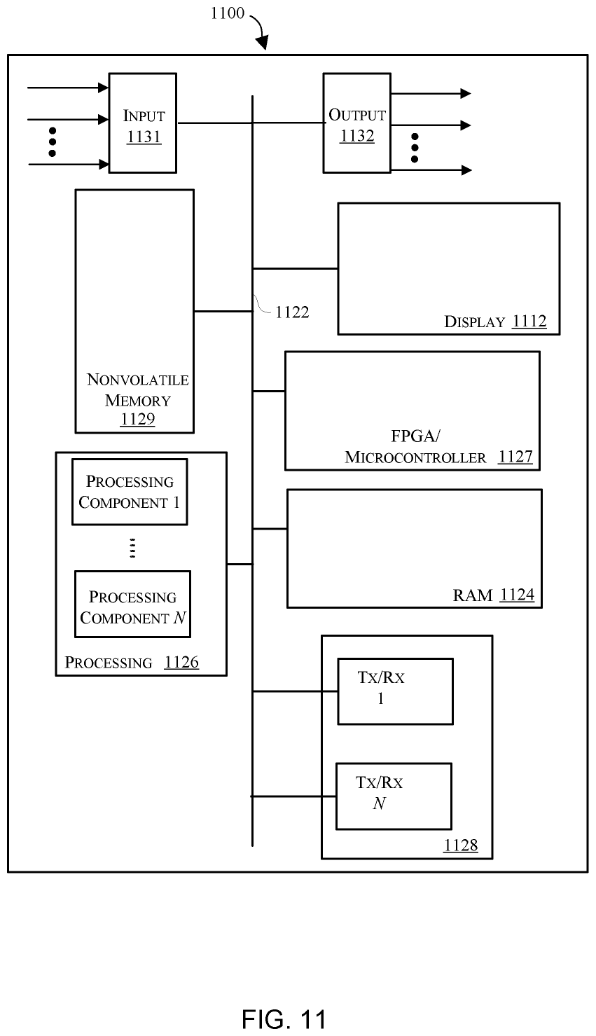

FIG. 11 illustrates a block diagram of a computer system 1100 that may be used to implement one or more aspects of the present disclosure, including at least a method for switching two or more PIN diodes in and out of an impedance match network (e.g., described above in relation to FIG. 10B). As shown, in this embodiment a display 1112 and nonvolatile memory 1129 are coupled to a bus 1122 that is also coupled to random access memory (“RAM”) 1124, a processing portion (which includes N processing components) 1126, a field programmable gate array (FPGA) 1127, and a transceiver component 1128 that includes N transceivers. Although the components depicted in FIG. 11 represent physical components, FIG. 11 is not intended to be a detailed hardware diagram; thus, many of the components depicted in FIG. 11 may be realized by common constructs or distributed among additional physical components. Moreover, other existing and yet-to-be developed physical components and architectures may also be utilized to implement the functional components described with reference to FIG. 11.

A display 1112 generally operates to provide a user interface for a user, and in several implementations, display 1112 is realized by a touchscreen display. For example, display 1112 can be used to control and interact with the components described herein. In general, nonvolatile memory 1129 is non-transitory memory that functions to store (e.g., persistently store) data and machine readable (e.g., processor executable) code (including executable code that is associated with effectuating the methods described herein). In some embodiments, for example, nonvolatile memory 1129 includes bootloader code, operating system code, file system code, and non-transitory processor-executable code to facilitate the execution of the methods described herein, such as method(s) 1000 in FIGS. 10A-B.

In some implementations, nonvolatile memory 1129 may be realized by flash memory (e.g., NAND or ONENAND memory). In other examples, other memory types may be utilized as well. Although some examples may execute the code from the nonvolatile memory 1129, in other examples, the executable code in the nonvolatile memory may typically be loaded into RAM 1124 and executed by one or more of the N processing components in the processing portion 1126.

In operation, the N processing components in connection with RAM 1124 may generally operate to execute the instructions stored in nonvolatile memory 1129 to realize the functionality of the PIN diode switch system described herein. For example, non-transitory processor-executable instructions to effectuate the methods described herein may be persistently stored in nonvolatile memory 1129 and executed by the N processing components in connection with RAM 1124. Processing portion 1126 may include a video processor, digital signal processor (DSP), graphics processing unit (GPU), and other processing components.

In addition, or in other examples, the field programmable gate array (FPGA) 1127 may be configured to effectuate one or more aspects of the methodologies described herein. For example, non-transitory FPGA-configuration-instructions may be persistently stored in nonvolatile memory 1129 and accessed by the FPGA 1127 (e.g., during boot up) to configure the FPGA 1127.

The input component 1131 may generally operate to receive signals (e.g., frequency of high frequency or RF signal, magnitude of current to be supplied through the series connected PIN diodes, magnitude of reverse bias voltage to be supplied across the series connected PIN diodes, to name a few). The output component 1132 may generally operate to provide one or more digital and/or analog signals (e.g., to a control module, to the PIN diode driver(s), etc.) to effectuate operational aspects of a PIN diode switch system, and/or other system described herein. In some embodiments, the computer system 1100 may be used in conjunction with one or more of the PIN diode switches described herein for driving the series connected PIN diodes in the PIN diode switch. Additionally, or alternatively, the computer system 1100 may be configured to perform a method for switching two or more PIN diodes in and out of an impedance match network.

The depicted transceiver component 1128 includes N transceiver chains, which may be used for communicating with external devices (e.g., external controllers) via wireless or wireline networks. Each of the N transceiver chains may represent a transceiver associated with a particular communication scheme (e.g., WiFi, Ethernet, Profibus, etc.).

Methods 1000-a and 1000-b and other methods of this disclosure may include other steps or variations in various other embodiments. Some or all of any of method(s) 1000 may be performed by or embodied in hardware, and/or performed or executed by a controller, a CPU, an FPGA, a System on Chip (SoC), a Measurement and Control Multi-Processor System on Chip (MPSoC), which may include both a CPU and an FPGA, and other elements together in one integrated SoC, or other processing device or computing device processing executable instructions, in controlling other associated hardware, devices, systems, or products in executing, implementing, or embodying various subject matter of the method.

### ADDITIONAL EMBODIMENTS

Some embodiments of the disclosure may be characterized as a method for driving PIN diodes in a PIN diode switch, the method comprising: providing series connected PIN diodes, wherein providing the series connected PIN diodes comprises connecting two or more PIN diodes in series; connecting a first radio frequency (RF) bypass capacitor between a reference node and a first end of the series connected PIN diodes; connecting a second RF bypass capacitor between the reference node and a second end of the series connected PIN diodes; connecting an RF circuit between the reference node and an internal node of the series connected PIN diodes, wherein the internal node is positioned between a first end of a first PIN diode of the two or more PIN diodes and a second end of a second PIN diode of the two or more PIN diodes, and wherein the first PIN diode is adjacent the second PIN diode; connecting a first PIN diode driver across the first RF bypass capacitor; and connecting a second PIN diode driver across the second RF bypass capacitor.

In some embodiments of the method described above, the first PIN diode driver and the second PIN diode driver are complementary to each other and configured to generate currents and voltages of opposing polarity.

In some embodiments of the methods described above, the first PIN diode driver and the second PIN diode driver are configured to: supply a current through the series connected PIN diodes to switch the series connected PIN diodes to an ON state; and supply a reverse bias voltage across the series connected PIN diodes to switch the series connected PIN diodes to an OFF state, wherein the magnitude of an impedance presented to the RF circuit connected between the internal node and the reference node is higher when the series connected PIN diodes are in the OFF state as compared to when the series connected PIN diodes are in the ON state.

In some embodiments of the methods described above, the PIN diode switch is connected to a RF impedance matching network comprising one or more reactance elements, wherein the PIN diode switch is further configured to connect or disconnect at least one reactance element of the one or more reactance elements from a remainder of the RF impedance matching network.

In some embodiments of the methods described above, each of the first PIN diode driver and the second PIN diode driver are two-stage drivers, comprising (1) a first resonant stage having a power supply; one or more of switches and reactive elements for charging and discharging a respective one of the first and the second RF bypass capacitors, the series connected PIN diodes, and one or more capacitive elements in the RF circuit from and to the power supply, and (2) a second holding stage for either holding a reverse bias voltage over the series connected PIN diodes or supplying a current through the series connected PIN diodes. In some cases, the PIN diodes are in an OFF state when the reverse bias voltage is applied and in an ON state when current is supplied through the PIN diodes.

Some embodiments of the method described above, further include connecting an RF choke (e.g., inductor) between the internal node and the reference node, where the RF choke is configured to block RF signals and pass DC signals.

As used herein, the term “Radiofrequency” or “RF” should be understood to also encompass “Alternating Current” or “AC”. For example, an AC bypass capacitor may be used in lieu of an RF bypass capacitor. Similarly, AC circuitry may be used in lieu of RF circuitry, in some embodiments.

As used herein, the recitation of “at least one of A, B and C” is intended to mean “either A, B, C or any combination of A, B and C.” The previous description of the disclosed embodiments is provided to enable any person skilled in the art to make or use the present disclosure. Various modifications to these embodiments will be readily apparent to those skilled in the art, and the generic principles defined herein may be applied to other embodiments without departing from the spirit or scope of the disclosure. Thus, the present disclosure is not intended to be limited to the embodiments shown herein but is to be accorded the widest scope consistent with the principles and novel features disclosed herein.

It will be understood that, although the terms first, second, third, etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of the present disclosure.

Spatially relative terms, such as “beneath,” “below,” “lower,” “under,” “above,” “upper,” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” or “under” other elements or features would then be oriented “above” the other elements or features. Thus, the exemplary terms “below” and “under” can encompass both an orientation of above and below. The device may be otherwise oriented (e.g., rotated 90 degrees or at other orientations) and the spatially relative descriptors used herein interpreted accordingly. In addition, it will also be understood that when a layer is referred to as being “between” two layers, it can be the only layer between the two layers, or one or more intervening layers may also be present.

The terminology used herein is for the purpose of describing particular embodiments only and is not intended to be limiting of the disclosure. As used herein, the singular forms “a,” “an,” and “the” are intended to include the plural forms as well, unless the context clearly indicates otherwise. It will be further understood that the terms “comprises” and/or “comprising,” when used in this specification, specify the presence of stated features, integers, steps, operations, elements, components, and/or groups but do not preclude the presence or addition of one or more other features, integers, steps, operations, elements, components, and/or groups thereof. As used herein, the term “and/or” includes any and all combinations of one or more of the associated listed items and may be abbreviated as “/”.

It will be understood that when an element or layer is referred to as being “on,” “connected to,” “coupled to,” or “adjacent to” another element or layer, it can be directly on, connected, coupled, or adjacent to the other element or layer, or intervening elements or layers may be present. In contrast, when an element is referred to as being “directly on,” “directly connected to,” “directly coupled to,” or “immediately adjacent to” another element or layer, there are no intervening elements or layers present.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and/or the present specification and will not be interpreted in an idealized or overly formal sense unless expressly so defined herein.

What is claimed is:

1. An apparatus comprising:
series connected PIN diodes, the series connected PIN diodes comprising:
two or more PIN diodes connected in series between a first end and a second end; and
an internal node positioned between two of the two or more PIN diodes;
a first radio frequency (RF) bypass capacitor connected between a reference node and the first end of the series connected PIN diodes, and wherein a second end of the series connected PIN diodes is connected to the reference node;
an RF circuit connected between the reference node and the internal node; and
a first PIN diode driver connected across the first RF bypass capacitor.

2. The apparatus of claim 1, wherein the series connected PIN diodes comprise an equal number of PIN diodes on either side of the internal node.

3. The apparatus of claim 1, wherein the first PIN diode driver is configured to one or more of:
supply a current through the series connected PIN diodes to turn the two or more PIN diodes ON; and
supply a reverse bias voltage across the series connected PIN diodes to turn the two or more PIN diodes OFF, and wherein a magnitude of an impedance presented to the RF circuit is higher when the two or more PIN diodes are OFF as compared to when the two or more PIN diodes are ON.

4. The apparatus of claim 3, wherein the apparatus is connected to a RF impedance matching network comprising one or more reactance elements, and wherein the apparatus is further configured to connect or disconnect at least one reactance element of the one or more reactance elements from a remainder of the RF impedance matching network.

5. The apparatus of claim 3, wherein the first PIN diode driver comprises a two-stage driver, the two-stage driver comprising:
a first resonant stage having a power supply;
one or more switches and reactive elements for charging and discharging one or more of the first RF bypass capacitor, the series connected PIN diodes, and one or more capacitive elements in the RF circuit from and to the power supply; and
a second holding stage configured to one or more of:
hold a reverse bias voltage over the series connected PIN diodes, wherein the series connected PIN diodes are in an OFF state when the reverse bias voltage is applied; and
supply current through the series connected PIN diodes, wherein the series connected PIN diodes are in an ON state when current is supplied through the series connected PIN diodes.

6. The apparatus of claim 1, wherein a second end of the series connected PIN diodes is connected to the reference node via a second RF bypass capacitor, the apparatus further comprising a second PIN diode driver connected across the second RF bypass capacitor.

7. The apparatus of claim 6, wherein the second PIN diode driver is a complementary PIN diode driver producing voltage and current of opposite polarity than that of the first PIN diode driver.

8. The apparatus of claim 6, further comprising a DC passing RF blocking device connected between the internal node and the reference node, wherein the DC passing RF blocking device presents low resistance to DC current and an impedance of large magnitude to RF current, and wherein the DC passing RF blocking device is selected from a group consisting of an inductor, a parallel combination of an inductor and a capacitor, and a quarter RF wavelength long transmission line.

9. The apparatus of claim 1, wherein the first radio frequency (RF) bypass capacitor comprises a plurality of capacitors connected in series, the apparatus further comprising:
a plurality of DC passing RF blocking devices connected between intermediary nodes of the plurality of capacitors connected in series and intermediary nodes of the series connected PIN diodes, and wherein the plurality of DC passing RF blocking devices present low resistance to DC current and an impedance of large magnitude to RF current.

10. A method for driving series connected PIN diodes in a PIN diode switch, the series connected PIN diodes comprising two or more PIN diodes connected in series between a first end and a second end, the method comprising:
supplying a current through the series connected PIN diodes to forward bias and turn the series connected PIN diodes ON, wherein RF circuitry is coupled between a reference node and an internal node, and a first RF bypass capacitor is connected between the first end of the series connected PIN diodes and the reference node, the internal node positioned between two of the two or more PIN diodes; and
supplying a reverse bias voltage across the series connected PIN diodes to turn the series connected PIN diodes OFF, wherein
when the series connected PIN diodes are ON, a first impedance is presented to the RF circuitry and when the series connected PIN diodes are OFF, a second impedance is presented to the RF circuitry, and wherein
a magnitude of the second impedance is greater than a magnitude of the first impedance.

11. The method of claim 10, wherein the second end of the series connected PIN diodes is coupled to the reference node.

12. The method of claim 11, wherein the second end of the series connected PIN diodes is coupled to the reference node via a second RF bypass capacitor.

13. The method of claim 12, wherein a first PIN diode driver is connected across the first RF bypass capacitor and a second PIN diode driver is connected across the second RF bypass capacitor.

14. The method of claim 13, wherein the second PIN diode driver is a complementary PIN diode driver producing voltages and currents with opposite polarity than that of the first PIN diode driver.

15. The method of claim 10, further comprising charging and discharging one or more of the first RF bypass capacitor, the series connected PIN diodes, and one or more capacitive elements in the RF circuitry from and to a power supply of a first resonant stage of a two-stage driver coupled across the first RF bypass capacitor.

16. The method of claim 15, further comprising holding the reverse bias voltage across the series connected PIN diodes via a holding stage of the two-stage driver connected across the first RF bypass capacitor.

17. The method of claim 15, further comprising supplying the current through the series connected PIN diodes via a holding stage of the two-stage driver connected across the first RF bypass capacitor.

18. The method of claim 10, further comprising disconnecting at least one reactance element in an impedance matching network when the series connected PIN diodes are OFF.

19. A non-transitory, tangible computer readable storage medium, encoded with processor readable instructions to perform a method for switching two or more PIN diodes in and out of an impedance match network, the method comprising:
supplying a current through the two or more PIN diodes to forward bias and turn the two or more PIN diodes ON, wherein RF circuitry is coupled between a reference node and an internal node, and a first RF bypass capacitor is connected between the first end of the two or more PIN didoes and the reference node, the internal node positioned between two of the two or more PIN diodes; and
supplying a reverse bias voltage across the two or more PIN diodes to turn the two or more PIN diodes OFF, wherein
when the two or more PIN diodes are ON, a first impedance is presented to the RF circuitry and when the two or more PIN diodes are OFF, a second impedance is presented to the RF circuitry, and wherein
a magnitude of the second impedance is greater than a magnitude of the first impedance.

20. The non-transitory, tangible computer readable storage medium of claim 19, wherein the supplying the reverse bias voltage comprises:
supplying a first voltage to remove charges from an intrinsic region of each of the two or more PIN diodes; and
supplying the reverse bias voltage to maintain the two or more PIN diodes OFF, wherein a magnitude of the first voltage is less than a magnitude of the reverse bias voltage.
